(19) United States
(12) Patent Application Publication
(10) Pub. No.: US 2014/0369527 A1
(43) Pub. Date: Dec. 18, 2014

(54) DYNAMIC RANGE CONTROL

(71) Applicant: Earsoft Limited, Somerset (GB)

(72) Inventor: Stephen Baldwin, Worcestershire (GB)

(21) Appl. No.: 14/345,614

(22) PCT Filed: Sep. 21, 2012
(86) PCT No.: PCT/GB2012/052339

§ 371 Date: Mar. 18, 2014

(30) Foreign Application Priority Data
Sep. 22, 2011 (GB) 1116348.2
Sep. 22, 2011 (GB) 1116349.0

(51) Int. Cl. H03G 3/20

(52) U.S. Cl. CPC H03G 3/20
USPC 381/107

(57) ABSTRACT

A computer-implemented method of dynamic range control is disclosed. The method includes at a device with a display, displaying a volume (relative loudness level) control to control the volume level of an output audio signal of the device, the volume control including a dynamic resizable window control for controlling the dynamic range of the output audio signal. A method for adjusting dynamic range of an audio signal is also disclosed. The method includes providing an input audio signal with a first dynamic range, mapping the first dynamic range to a second dynamic range using a transfer function with a linear portion aligned to an average level of the input audio signal, and generating an output audio signal with the second dynamic range from the input audio signal.

### BACKGROUND

Dynamic range (for audio) generally describes the ratio of the softest sound to the loudest sound for a piece of audio, a musical instrument or piece of electronic equipment, and is measured in decibels (dB). Dynamic range measurements are used in audio equipment to indicate a component's maximum output signal and to rate a system's noise floor. For example, the dynamic range of human hearing, which is the difference between the softest and loudest sounds that a human can typically perceive, is around 120 dB.

In a noisy listening environment, quiet sections of audio at the lower end of its dynamic range can be obscured by ambient noise. To prevent this, it is typical for the dynamics to be compressed during mastering so that the relative level of quiet and loud parts of the signal is made more similar. For example, modern audio, such as music or television audio normally has a small dynamic range. By reducing the dynamic range of the signal, the audibility of the dynamics is reduced. Reducing the dynamic range is not optimal when it is desired to maximise the total audibility in all listening environments.

This requirement for the signal to be louder than the noise, but not so loud that it is uncomfortable, leads to the definition of the dynamic range tolerance (DRT) of a listening environment. The DRT alters depending on the listener's mood and requirements for the audio (for example, whether the audio is being used as background or for active listening). A larger dynamic range is associated with a greater difference between peak and root-mean-square (RMS) signal level. Therefore, in a better listening environment, a similarly greater difference between these is tolerated.

Typically, devices which are capable of audio or video playback do not allow a user to adjust settings for output audio other than a volume level. Some devices and systems do allow settings to be managed, but the complexity of the options provided can be detrimental and often lead to poor results. It should be noted that throughout this application the use of the term “volume” should be interpreted to include relative loudness level.

### SUMMARY

According to an example there is provided computer-implemented method, comprising at a device with a display: displaying a volume (relative loudness level) control to control the volume level of an output audio signal of the device, the volume control including a dynamic resizable window control to control dynamic range of the output audio signal, and processing an input audio signal to constrain an average value of the volume for that signal within a selected central region of the window control to control the dynamic range of the output audio signal. Upper and lower bounds of the control represent upper and lower bounds for the dynamic range of the output audio signal.

The device can be a touch screen display device, the method further comprising detecting a translation gesture for the window control by one or more fingers on or near the touch screen display, and in response to detecting the translation gesture, adjusting the position of the window control to modify the volume of the output audio signal. In an example, the method can include detecting a resizing gesture for the window control by one or more fingers on or near the touch screen display, and in response to detecting the resizing gesture, adjusting the size of the window control to modify the dynamic range of the output audio signal. A resizing gesture can include at least one finger tap on or near the touch screen display in the vicinity of the control window. A resizing gesture can include a pinch or anti-pinch gesture using at least two fingers. In an example, a resizing gesture can cyclically resize the window control between multiple discrete sizes.

The method can include detecting a translation gesture for the window control by an input device, and in response to detecting the translation gesture, adjusting the position of the window control to modify the volume of the output audio signal. The method can further include detecting a resizing gesture for the window control by an input device, and in response to detecting the resizing gesture, adjusting the size of the window control to modify the dynamic range of the output audio signal. A resizing gesture can include executing a control button operation in the vicinity of the control window. A mode selection control can be used for selecting a mode of operation for the dynamic resizable window control representing one of multiple modes with respective different ranges for the dynamic range of the output audio signal. An average volume level over a predetermined period of time can be substantially aligned with the centre of the dynamic resizable window control. The window control can be moveable within a predetermined volume range, the method further comprising shrinking the range of the dynamic resizable window control in response to the window control impinging on a portion of the predetermined volume range at either extreme of said range to provide a reduced window control. In an example, the dynamic resizable window control can be shrunk to a predetermined minimum.

The method can further include providing a volume level for the output audio signal in response to user input to shift the reduced window control past the portion at an extreme of the predetermined volume range. A mute control can be provided accessible via the mode selection control to mute the output audio signal.

According to an example there is provided a graphical user interface on a device with a display, comprising a volume control portion to display a volume level for an output audio signal and to provide a range within which the volume level can be adjusted, a dynamic range control portion including an adjustable window element aligned with the volume control portion to define a dynamic range for the output audio signal. The size of the window element can define the dynamic range of the output audio signal. A size of the window element can be cyclically adjusted between multiple discrete sizes. Adjusting a size of the window element can be effected using any one or more of: one or more finger taps on a touch screen display for the device, user input from an input device for the device, and a resizing gesture on a touch display for the device. The resizing gesture can be a pinch or anti-pinch using two or more fingers.

In an example, the graphical user interface as can further include a mode selection, and mute and reset selection controls.

According to an example there is provided a device, comprising a display,

one or more processors, memory, and one or more programs stored in the memory and including instructions which are configured to be executed by the one or more processors to display a volume control module to control a volume level and a dynamic range for an output audio signal output from the device, control the size and position of a dynamic range control window in response to user input, and control a dynamic range of the output audio signal on the basis of the size and position of the dynamic range control window by constraining an average value of the volume for an input audio signal within a selected central region of the control window.

The one or more processors can be further operable to execute instructions to receive first user input data representing a position for the dynamic range control window, and receive second user input data representing a size for the dynamic range control window. The second user input data can be generated in response to one or more of: a tap, pinch or anti-pinch gesture on the display.

According to an example, there is provided a method for adjusting dynamic range of an audio signal comprising providing an input audio signal with a first dynamic range, mapping the first dynamic range to a second dynamic range using a transfer function with a linear portion aligned to an average level of the input audio signal, and generating an output audio signal with the second dynamic range from the input audio signal. The average level of the input audio signal can be determined using a one pole low pass filter in combination with an absolute sum and average of the input audio signal with an averaging length greater than a predetermined minimum value. The method can further comprise aligning the linear portion to the average level using a gain value to shift the transfer function with respect to the input audio signal. User input representing a dynamic range window can be used to substantially constraining the second dynamic range of the output audio signal. In an example, the transfer function is determined on the basis of the user input, and can be dynamically adjusted in response to changes in a noise floor of the listening environment. The measurement can be adjusted to account for the output audio signal. In an example, a fade-in or fade-out portion of the input audio signal is maintained. This can be by preserving a noise floor of the input audio signal.

According to an example there is provided a method for configuring the dynamic range of an output audio signal, comprising providing a dynamic range tolerance window, computing an average value for an input audio signal over a predetermined psychoacoustic timescale, using the average to generate a gain value to shift the dynamic range tolerance window, and using the input audio signal to generate the output audio signal, the output audio signal having a dynamic range substantially confined within the dynamic range tolerance window. In an example, the average level of the input audio signal can be determined using a one pole low pass filter in combination with an absolute sum and average of the input audio signal with an averaging length greater than a predetermined minimum value. User input defining the dynamic range tolerance window can be received. A fade-in or fade-out portion of the input audio signal can be maintained.

According to an example there is provided a system for processing an audio signal, comprising a signal processor to receive data representing an input audio signal, map the dynamic range of the input audio signal to an output dynamic range using a transfer function with a linear portion aligned to an average level of the input audio signal, generate an output audio signal with the output dynamic range, from the input audio signal. The average level of the input audio signal can be determined using a one pole low pass filter in combination with an absolute sum and average of the input audio signal with an averaging length greater than a predetermined minimum value. The signal processor is further operable to align the linear portion to the average level using a gain value to shift the transfer function with respect to the input audio signal. In an example, user input representing a dynamic range window for substantially constraining the dynamic range of the output audio signal can be received. A transfer function can be determined on the basis of user input. The signal processor can adjust the transfer function in response to changes in a noise floor of the listening environment, and can maintain a fade-in or fade-out portion of the input audio signal.

According to an example there is provided a computer program embedded on a non-transitory tangible computer readable storage medium, the computer program including machine readable instructions that, when executed by a processor, implement a method for adjusting dynamic range of an audio signal comprising receiving data representing a user selection for a dynamic range tolerance, determining a transfer function based on the dynamic range tolerance, processing an input audio signal to generate an output audio signal using the transfer function by maintaining an average level of the input audio signal within a range defined by the user selection.

### BRIEF DESCRIPTION OF THE DRAWINGS

An embodiment of the invention will now be described, by way of example only, and with reference to the accompanying drawings, in which:

FIG. 1 is a schematic block diagram of a device according to an example;

FIG. 2 is a schematic block diagram of a device according to an example;

FIG. 3 is a schematic block diagram of a dynamic range control according to an example;

FIG. 4a-d are schematic block diagrams of a dynamic range control according to an example;

FIGS. 5a-c are schematic block diagrams of a dynamic range control according to an example;

FIG. 6 is a schematic block diagram of a dynamic range control according to an example;

FIGS. 7a-c are schematic block diagrams of a dynamic range control according to an example;

FIG. 8 is a schematic block diagram of a method according to an example;

FIG. 9 is a schematic representation of a transfer function according to an example;

FIG. 10 is a schematic block diagram of an averaging method according to an example;

FIG. 11 is a schematic block diagram of a method for processing a stereo signal according to an example;

FIG. 12 is a schematic block diagram of a method according to an example;

FIG. 13 is a schematic representation of the overall macro dynamics of a song according to an example;

FIG. 14 is a schematic representation of the overall macro dynamics of the song of FIG. 6 following processing using a method according to an example; and

FIG. 15 is a schematic block diagram of a device according to an example.

### DETAILED DESCRIPTION

It will be understood that, although the terms first, second, etc. may be used herein to describe various elements, these elements should not be limited by these terms. These terms are only used to distinguish one element from another. For example, a first gesture could be termed a second gesture, and, similarly, a second gesture could be termed a first gesture.

The terminology used herein is for the purpose of describing particular examples only and is not intended to be limiting. As used herein, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Examples of a device such as a portable multifunction device, user interfaces for such devices, and associated processes for using such devices are described. According to some examples, the device can be a portable communications and music and/or video playback device such as a mobile telephone that also contains other functions, such as FDA for example. The device can be a music playback device, a video playback device, or any other device capable of providing an audio signal for output, either for one or more speakers or headphones for example. For example, the device can be a computing apparatus which provides an audio output from locally or remotely stored data.

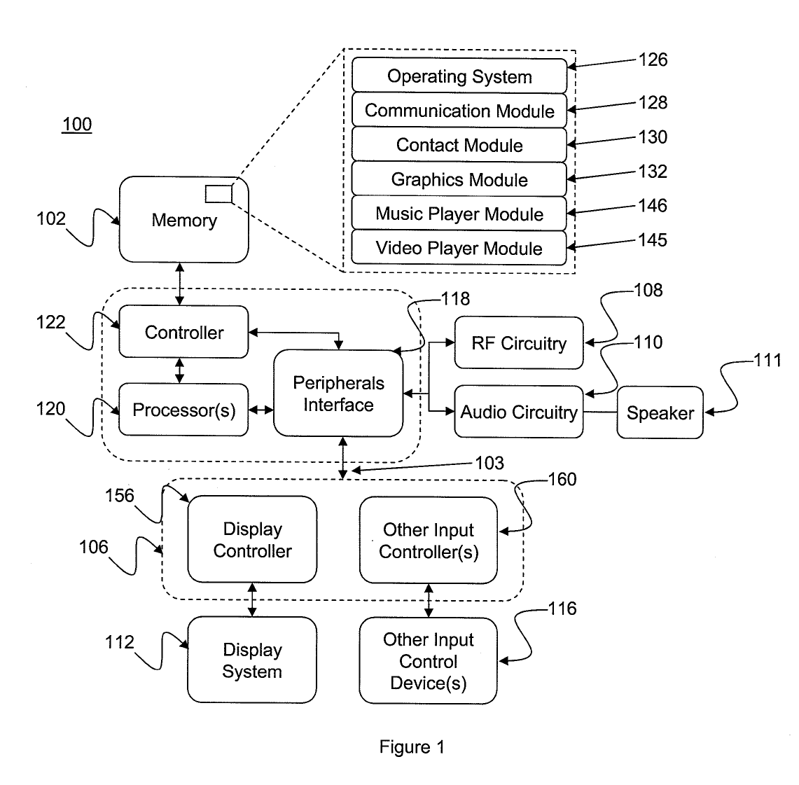

FIG. 1 is a schematic block diagram of a device 100 according to an example. In some examples, the device 100 includes a touch-sensitive display system 112. The touch-sensitive display system 112 is sometimes called a “touch screen” for convenience. The device 100 may include a memory 102 (which may include one or more computer readable storage mediums), a memory controller 122, one or more processing units (CPU's) 120, a peripherals interface 118. RF circuitry 108, audio circuitry 110, a speaker 111, an input/output (I/O) subsystem 106 and other input or control devices 116. These components may communicate over one or more communication buses or signal lines 103.

It should be appreciated that the device 100 is only one example of a device 100, and that the device 100 may have more or fewer components than shown in FIG. 1, may combine two or more components, or a may have a different configuration or arrangement of the components than that shown. The various components shown in FIG. 1 may be implemented in hardware, software or a combination of both hardware and software, including one or more signal processing and/or application specific integrated circuits for example.

Memory 102 may include high-speed random access memory and may also include non-volatile memory, such as one or more magnetic disk storage devices, flash memory devices, or other non-volatile solid-state memory devices. Access to memory 102 by other components of the device 100, such as the CPU 120 and the peripherals interface 118, may be controlled by the memory controller 122.

The peripherals interface 118 couples the input and output peripherals of the device to the CPU 120 and memory 102. The one or more processors 120 run or execute various software programs and/or sets of machine readable instructions stored in memory 102 to perform various functions for the device 100 and to process data.

In some embodiments, the peripherals interface 118, the CPU 120, and the memory controller 122 may be implemented on a single chip, such as a chip 104. In some other embodiments, they may be implemented on separate chips.

The RF (radio frequency) circuitry 108 receives and sends RF signals. The RF circuitry 108 converts electrical signals to/from electromagnetic signals and communicates with communications networks and other communications devices via the electromagnetic signals. The RF circuitry 108 may include well-known circuitry for performing these functions, including but not limited to an antenna system, an RF transceiver, one or more amplifiers, a tuner, one or more oscillators, a digital signal processor, a CODEC chipset, a subscriber identity module (SIM) card, memory, and no forth. The RF circuitry 108 may communicate with networks, such as the Internet, an intranet and/or a wireless network, such as a cellular telephone network, a wireless local area network (LAN), and other devices by wireless communication. The wireless communication may use any of a plurality of communications standards, protocols and technologies.

The audio circuitry 110 and the speaker 111 provide an audio interface between a user and the device 100. The audio circuitry 110 receives audio data from the peripherals interface 118, converts the audio data to an electrical signal, and transmits the electrical signal to the speaker 111. The speaker 111 converts the electrical signal to human-audible sound waves. Audio data may be retrieved from and/or transmitted to memory 102 and/or the RF circuitry 108 by the peripherals interface 118. In some examples, the audio circuitry 110 also includes a headset jack. The headset jack provides an interface between the audio circuitry 110 and removable audio input/output peripherals, such as output-only headphones or a headset with both output (e.g., a headphone for one or both ears) and input (e.g., a microphone).

The I/O subsystem 106 couples input/output peripherals on the device 100, such as the touch screen 112 and other input/control devices 116, to the peripherals interface 118. The I/O subsystem 106 may include a display controller 156 and one or more input controllers 160 for other input or control devices. The one or more input controllers 160 receive/send electrical signals from/to other input or control devices 116. The other input/control devices 116 may include physical buttons (e.g., push buttons, rocker buttons, etc.), dials, slider switches, joysticks, click wheels, trackpads, touch interface devices and so forth. In some alternate embodiments, input controller(s) 160 may be coupled to any (or none) of the following: a keyboard, infrared port. USB port, and a pointer device such as a mouse. The one or more buttons may include an up/down button for volume (relative loudness level) control of the speaker 111. The one or more buttons may include a push button or slider control. The touch screen 112 can be used to implement virtual or soft buttons or other control elements and modules for a user interface for example.

The touch-sensitive touch screen 112 provides an input interface and an output interface between the device and a user. The display controller 156 receives and/or sends electrical signals from/to the touch screen 112. The touch screen 112 displays visual output to the user. The visual output may include graphics, text, icons, video, and any combination thereof. In some embodiments, some or all of the visual output may correspond to user-interface objects, further details of which are described below.

A touch screen 112 has a touch-sensitive surface, sensor or set of sensors that accepts input from the user based on haptic and/or tactile contact. The touch screen 112 and the display controller 156 (along with any associated modules and/or sets of instructions in memory 102) detect contact (and any movement or breaking of the contact) on the touch screen 112 and converts the detected contact into interaction with user-interface objects that are displayed on the touch screen or another display device. In an example, a point of contact between a touch screen 112 and the user corresponds to a finger of the user.

The touch screen 112 and the display controller 156 may detect contact and any movement or breaking thereof using any of a plurality of typical touch sensing technologies, including but not limited to capacitive, resistive, infrared, and surface acoustic wave technologies, as well as other proximity sensor arrays or other elements for determining one or more points of contact with a touch screen 112.

In some example, software components stored in memory 102 may include an operating system 126, a communication module (or set of instructions) 128, a contact module (or set of instructions) 130, a graphics module (or set of instructions) 132, a music player module 146 and a video player module 145.

The communication module 128 facilitates communication with other devices over one or more external ports (not shown). The contact/motion module 130 may detect contact with the touch screen 112 (in conjunction with the display controller 156) and other touch sensitive devices (e.g., a touchpad or physical click wheel). The contact module 130 includes various software components for performing various operations related to detection of contact, such as determining if contact has occurred, determining if there is movement of the contact and tracking the movement across the touch screen 112, and determining if the contact has been broken (i.e., if the contact has ceased). Determining movement of the point of contact may include determining speed (magnitude), velocity (magnitude and direction), and/or an acceleration (a change in magnitude and/or direction) of the point of contact. These operations may be applied to single contacts (e.g., one finger contacts) or to multiple simultaneous contacts (e.g., multiple finger contacts).

The graphics module 132 includes various known software components for rendering and displaying graphics on the touch screen 112, including components for changing the intensity of graphics that are displayed. As used herein, the term “graphics” includes any object that can be displayed to a user, including without limitation text, icons (such as user-interface objects), digital images, videos, animations and the like.

In conjunction with touch screen 112, display controller 156, contact module 130, graphics module 132, audio circuitry 110, and speaker 111, the video player module 145 may be used to display, present or otherwise play back videos (e.g., on the touch screen or on an external, connected display via external port).

In conjunction with touch screen 112, display system controller 156, contact module 130, graphics module 132, audio circuitry 110, speaker 111, RF circuitry 108, and browser module 147, the music player module 146 allows the user receive and play back recorded music and other sound files stored in one or more file formats, such as MP3 or AAC files. In some examples, the device 100 may include the functionality of an MP3 player.

Each of the above identified modules and applications correspond to a set of instructions for performing one or more functions described above. These modules (i.e., sets of instructions) need not be implemented as separate software programs, procedures or modules, and thus various subsets of these modules may be combined or otherwise re-arranged in various embodiments. For example, video player module 145 may be combined with music player module 146 into a single module (e.g., video and music player module). In some examples, memory 102 may store a subset of the modules and data structures identified above. Furthermore, memory 102 may store additional modules and data structures not described above.

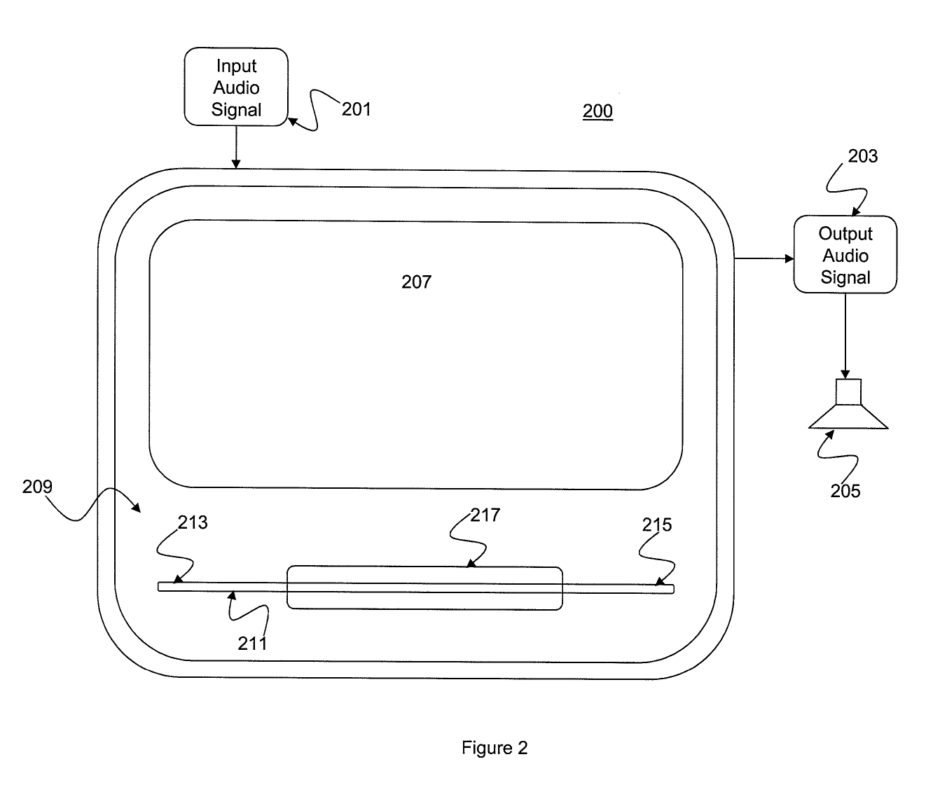

FIG. 2 is a schematic block diagram of a device according to an example. Device 200 includes a display 209, which can be a touch sensitive display 112. Device 200 uses an input audio signal 201 to provide an output audio signal 203 which can be provided to a speaker 205 or similar audio output device, such as headphones for example. A first display portion 207 of device 200c can be used to present information to a user. For example, the display portion 207 can be used to display video or other information to a user, such as information relating to the input or output audio signals for example.

A volume control for the device 200 is depicted generally by the bar 211. Such controls can typically take a number of forms ranging from bars and lines and so forth which define a range for adjustment of the volume (relative loudness level) for the device 200, to numerical controls for example. Control 211 has two end-points depicted generally at 213 and 215. The area around 213 is typically considered to be the lower end of the range for a volume or relative loudness level, whilst the area around 215 is typically considered to be the upper end of the range. According to an example, a control portion 217 is provided. The control 217 is in the form of a dynamic resizable window control which, in an example, is used for controlling the dynamic range of the output audio signal 203. The dynamic range control portion 217 includes an adjustable window element aligned with the volume control portion 211 to define a dynamic range for the output audio signal 203.

In an example, control 217 replaces the typical adjustment mechanism associated with volume control 211. Such mechanisms usually include movable points or icons which can be adjusted so as to change a volume level for the output audio signal 203. Control 217 can be transparent to allow volume control bar 211 to remain visible. Accordingly, a typical volume control which includes a volume control bar showing a range of volume levels which can be selected can be replaced with or augmented by a volume control bar 211 and dynamic range control 217. In an example, at least a dynamic range control 217 is provided which can be used to augment an existing volume control and replace a volume selection element associated therewith.

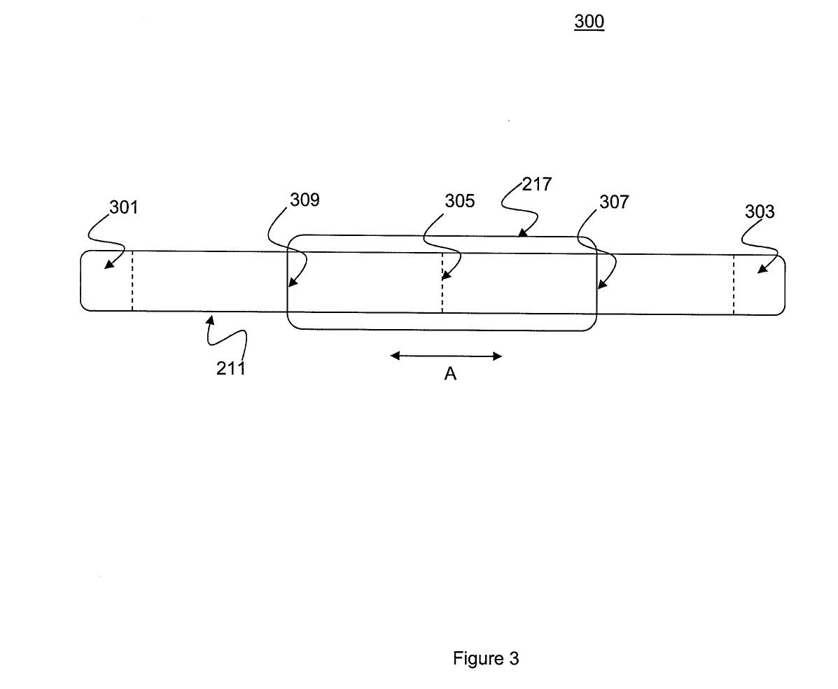

FIG. 3 is a schematic block diagram of a dynamic range control portion 300 according to an example. Similarly to that of FIG. 2, a volume control portion 211 is provided. The portion 211 is depicted as a bar, but it will be appreciated that any other suitable control portion can be used. For example, instead of a bar, a line can be used (either solid or otherwise). Control portion 217 includes an adjustable window element aligned with the volume control portion 211. In an example, control portion 217 is used to define a dynamic range for the output audio signal. Alignment of control portion 217 with volume control 211 can be effected in a number of ways. As depicted, there are two levels of alignment. Firstly, the control portion 217 is aligned so that it is parallel to the volume control 211. Secondly, the centre of the control portion 217 is aligned around a volume level 305. More specifically, the volume level 305 represents the current volume or loudness of the output audio signal. This level therefore fluctuates depending on the dynamic range of the output audio signal. Over a predetermined period of time, which can vary from the order of several seconds to several minutes, an average value for the level can be determined. This value is constrained so that it typically corresponds to a position which lies in the centre or a central region of the control portion 217. The dynamic range of the output audio signal 203 is therefore constrained within the range defined by the control portion 217.

The control portion 217 therefore defines a volume control. The upper and lower bounds of the control 217, depicted generally at 307 and 309 respectively, define a dynamic range for the output audio signal. That is, the dynamic range of the output audio signal is substantially constrained within the region defined by the control window of 217.

In an example, the control portion 217 is moveable with respect to the volume bar 211. For example, parallel alignment can be maintained, with the control portion movable back and forth along the volume control 211 in the directions depicted generally by the arrow A. As a result of volume level constraint as described above, moving the control 217 results in a change in the volume level and dynamic range of the output audio signal 203. As mentioned above, moving the control window 217 therefore results in a change of volume of the output audio signal since the window 217 has replaced the conventional volume level control associated with the volume control bar 211.

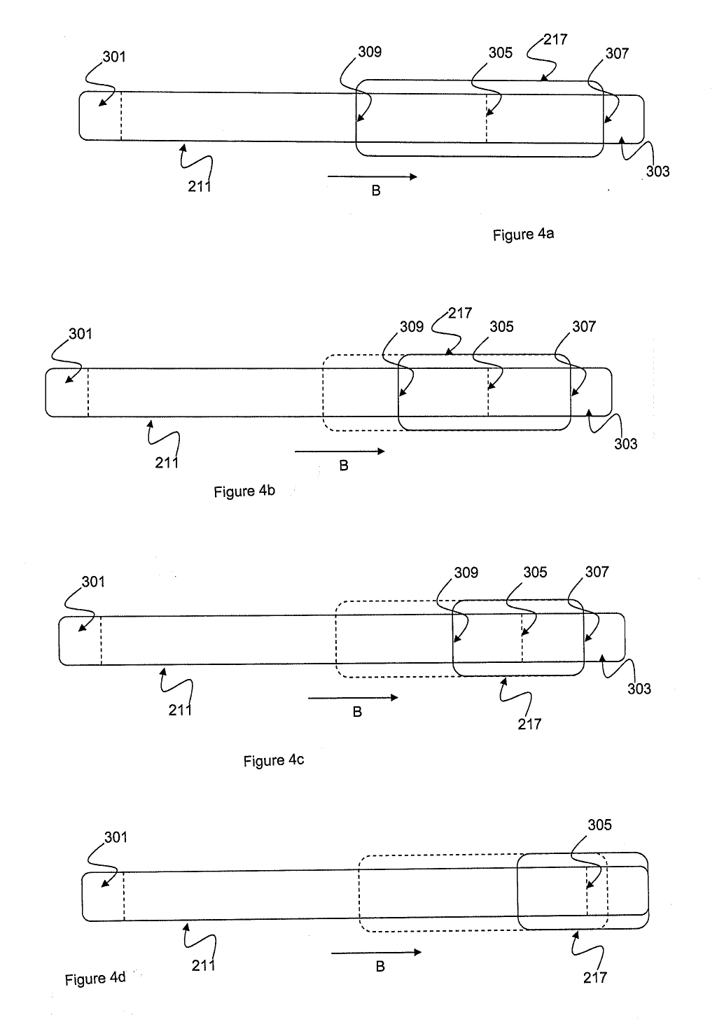

Regions 301 and 303 represent end regions for the volume control 211. Accordingly, region 301 represents a lower volume region in the volume control 211, and region 303 represents a higher volume region in the volume control 211. Adjusting the control 217 so that one or other of the end points 307, 309 impinge on the regions 301, 303 sets certain actions into effect according to an example, which are described below with reference to FIGS. 4a-d.

According to an example, control window 217 can be aligned at any angle, and can be any shape. For example, although the control 217 is described herein as including a rectangular window, it can be any shape, including curved shapes. For example, an arc shaped line or box can be used as a control window 217. Alternatively, the control 217 could be a donut shape, with or without a cut-out portion (that is, a complete donut shape, or a partial one). Other alternatives are possible, and it will be appreciated that the control 217 could be implemented in many ways to enable a user to be able select a desired volume level and dynamic range setting. Further it should be noted that control 217 and bar 211 can be aligned differently to that described, or can be distinct from one another, with control 217 being spatially separated or only partially overlapping bar 211 for example.

A user interface according to an example will typically have two interface-able areas visible at any one time, either a slide bar or window control 217 and a ‘mode/mute’ icon, module or control, or two ‘un-mute/chose’ mode icons, modules or controls. In an example, the slide bar 217 has a central region (which may or may not have a visual mark indicating its location) and two ends, one end is closest to the quieter end of the total range, and one end is closest to the louder end of the total range.

As described, the slide bar 217 can move and change length. Depending on the user interaction, mode icons can be visible or not visible, and, when visible can be dragged from one end of the slide bar 217 to the other in order to invoke a change in mode for example. Alternatively, mode changes can be effected in any number of other ways including, for example, by a user selecting a specific mode from a menu, or by highlighting an icon representing a desired mode. Alternatively, a mode can be selected automatically on the basis of a listening environment, and by taking into account the form of output device connected to a device, such as speakers or headphones for example. Mode icons provide a way for a user to select different operating modes of a device so that the characteristics of the output audio signal 203 can be adjusted. For example, a headphones mode and a speakers mode can be provided, each of which represent different ways in which an audio signal can be processed. For example, the characteristics of an output audio signal 203 can be different when in headphones mode compared to speakers mode.

A mute icon can appear or disappear. In an example, the mute icon is interacted with directly. A level meter can be present which moves in response to the output audio signal 203 to provide an indication of the volume level at a given time. The level meter can include representations for mono and stereo, such as single or double lines for example, and may also be provided with fast and slow meter response representations to provide a user with a better feel for the underlying sound.

According to an example, volume level bar 211 indicates to a user the total loudness range that is available to them. This range can be altered depending on the mode the user is in (such as either a speaker or headphone mode for example). Control 217 can replace a standard volume control. The control can be positioned and branded in order to fit with a desired theme for a content or system provider for example.

Muting of audio can be effected with a single tap (using a finger for example) or click (using an input device). This can be a tap or click on a mode icon for example. Un-muting the audio can be effected with a further tap or click, or by switching modes. In an example, muting causes the mute and mode icons to become visible. Accordingly, muting will allow a change in modes to be effected by a user selecting a mode icon for a desired mode. In order to switch modes with no gap in output audio, a mode icon can be dragged from one position to another position. For example, if mode icons are at either and of the volume bar 211, the mode icon for the currently active mode can be dragged to the position of the mode icon for the desired mode to effect the switch.

According to an example, the dynamic range provided by the control 217 can be quantised into multiple different ranges which can be accessed by a double tap or double click for example. Alternatively a pinch or anti-pinch touch gesture can be used to switch between the multiple different ranges. Selection of the ranges can be cyclic, such that the range reverts to a first range from a set of multiple ranges after the last and so on.

In an example, three such ranges can be provided. The first with the smallest dynamic range can be used for easy listening for example, and where a highly consistent sound is desired. The second range with a relatively larger dynamic range than the first range can be used for normal listening for example, and where a controlled output sound is desired. The third range with a relatively larger dynamic range than the second range can be used for audio signals where a large dynamic range is desired. All ranges can provide overall consistency, so from film-to-film, song-to-song, the overall loudness will typically be the same.

According to an example, the range offered by control 217 can be continuous rather than discrete. That is, control 217 can provide continuous adjustment for a dynamic range of an output audio signal 203 between predetermined minimum and maximum values with a user able to select any intermediate values for the range. In either case—continuous or discrete—a user can select a desired range using a number of different input mechanisms. As described, a double tap or click in or around the vicinity of control 217 can be used to cyclically switch between discrete ranges. For the continuous case, the user can ‘grab’ one end of the control 217 using a finger (for touch devices) or an input device (such as a mouse or trackpad for example), and drag it to increase or decrease the range. In this case, the position of the other end of the control 217 which was not ‘grabbed’ can be maintained, with the range being adjusted by virtue of movement of the grabbed end only. This can result in a change to the position of the volume level. Alternatively, the volume level can be maintained in its current position irrespective of the end of the control 217 which is moved. For example, grabbing and moving one end of control 217 can result in an equal (in magnitude) but opposite (in direction) adjustment of the other end of the control 217 so that the position of the volume level is maintained.

Alternatively, in a touch sensitive system (which can use a touch sensitive display or a trackpad and so on) a suitable touch gesture can be used to alter the size of the control 217. For example, a pinch or anti-pinch gesture can be used to cycle between range settings, or to adjust the size of the control 217. As above, the gesture can result in the volume level shifting or being maintained in a current position. For example, a touch gesture can be such that it allows either end of the control 217 to be adjusted at different rates, thereby resulting in a shift in the position of the volume level. Alternatively, the control 217 can react to a touch gesture in such a way that a consistent adjustment of both ends of the control 217 is obtained. That is, irrespective of the relative speed of adjustment of either end (using a pinch or anti-pinch for example), both ends of the range move at the same rate.

In an example, a single tap, click or similar or other gesture or command for the control window 217 can cause the volume level to be constrained to a central region of the range defined by the control window 217.

FIG. 4a is a schematic block diagram of a dynamic range control portion 217 according to an example. More specifically, FIG. 4a shows the dynamic range control 217 after having been moved by a user to increase the volume level of the output audio signal 203 by moving the control 217 in the direction of the arrow B. The upper region 307 of the control 217 impinges on or otherwise enters region 303. The average level 305 has increased accordingly. However, as the size (width) of the control 217 has not altered, the dynamic range of the output audio signal 203 has not been affected. The effect of further increasing the volume level by moving the control 217 in the direction of arrow B is shown in FIG. 4b. The volume level 305 of the output audio signal 203 is increased further. However, since the upper, region 303 of the volume control bar 211 has already been reached, the control window 217 shrinks. That is, continuing to shift the control 217 in the direction of arrow B causes the upper end 307 to contract in towards the lower end 309. The dynamic range, as defined by the width of the control window 217 is therefore reduced commensurate with the level by which the window is shrunk as a result of user shifting the control.

FIG. 4c shows that the control window 217 has shrunk (or has been minimised) to a predetermined minimum size. Attempting to shift the control window 217 further in the direction of arrow B has no effect on the size of the control window 217 as the minimum has already been reached. The minimum can be predetermined, or can be automatically determined on the basis of the listening environment for example. In order to step past the boundary of the predetermined maximum 303, a user can implement a specific action or actions which can cause the control window 217 to step to a maximum volume level with a corresponding dynamic range defined by the width of the window. In an example, stepping past the maximum 303 to reach a further higher volume level can be effected by a user discontinuing the shift of the window. Discontinuing can include releasing a finger or other suitable implement from a touch screen, or releasing a control device which is being used to shift the window for example. Upon further application of the control device, finger or other implement to shift the window after discontinuation, it can ‘jump’ past the boundary defining the upper region 303 in order to provide a further maximum setting for the output audio signal 203.

In an example, there are therefore multiple regions that the control 217 can occupy. The first is when it is at its full length for a given range setting. A user operation to increase or decrease the volume level causes the window 217 to move either in the increasing or decreasing volume/loudness direction. In this case, no change in the width of the window takes place. In the second case, the window control 217 is fixed at a predetermined offset from 0 dBFS. An attempt to increase the volume causes the range to shrink in size up to a predetermined minimum. A decrease in volume causes the window to extend towards its full length for the given range setting.

A desired increase in volume greater than a predetermined minimum, such as once the window has been reduced to its minimum size for example, causes the control to ‘jump’ so that its ‘loud extreme’ is at a different but higher predetermined value to that of the previous case in which the notional maximum volume was obtained. A difference of the order of 6 dB can be used for example compared to the notional maximum volume level.

At the other end of the scale, the quiet extreme of the window control 217 is fixed at a given off set from 0 dBFS of the order of −54 dBFS in an example. A decrease volume operation or event causes the window to shrink towards a lower volume level until the window is of a predetermined minimum range. An increase in the volume causes the window to extend in length until it reaches full length for the given range mode.

An event which seeks to decrease the volume by a magnitude greater than a predetermined minimum (once the window control has been reduced to the minimum size) can cause the window to ‘jump’ to a mute setting so that both the loud and quiet extreme are at −inf dB, or another suitably low setting which effectively results in a mute of the output audio signal. A mute icon can then be made visible in such an instance.

According to an example, predetermined dB values at which the window control transitions between states can be determined by the mode the device in question is in as will be described below. It should also be noted that although the values noted above for the various cases are indicative of suitable values, they are not intended to be limiting, and other alternative values which can be suitable for a given user, device or environment can be used.

FIGS. 5a-c are schematic block diagrams of a dynamic range control portion according to an example. FIG. 5a shows the dynamic range control 217 after having been moved by a user to decrease the volume level of the output audio signal 203 by moving the control 217 in the direction of the arrow C. The lower region 309 of the control 217 impinges on or otherwise enters region 301. The average level 305 has decreased accordingly. However, as the size (width) of the control 217 has not altered, the dynamic range of the output audio signal 203 has not been affected. The effect of further decreasing the volume level by moving the control 217 in the direction of arrow C is shown in FIG. 5b. The volume level 305 of the output audio signal 203 is decreased further. However, since the lower region 309 of the volume control bar 211 has already been reached the control window 217 shrinks. That is, continuing to shift the control 217 in the direction of arrow C causes the higher end 307 to contract in towards the lower end 309. The dynamic range, as defined by the width of the control window 217 is therefore reduced commensurate with the level by which the window is shrunk as a result of user shifting the control.

FIG. 5c shows that the control window 217 has shrunk (or has been minimised) to a predetermined minimum size. Attempting to shift the control window 217 further in the direction of arrow C has no effect on the size of the control window 217 as the minimum range and minimum volume level has already been reached. The minimum can be predetermined, or can be automatically determined on the basis of the listening environment for example. In an example, further shifting of the control 217 in the direction of arrow C once a minimum has been reached can result in audio being muted. This can require a user to ‘release’ the control and reassert the movement before a mute occurs for example.

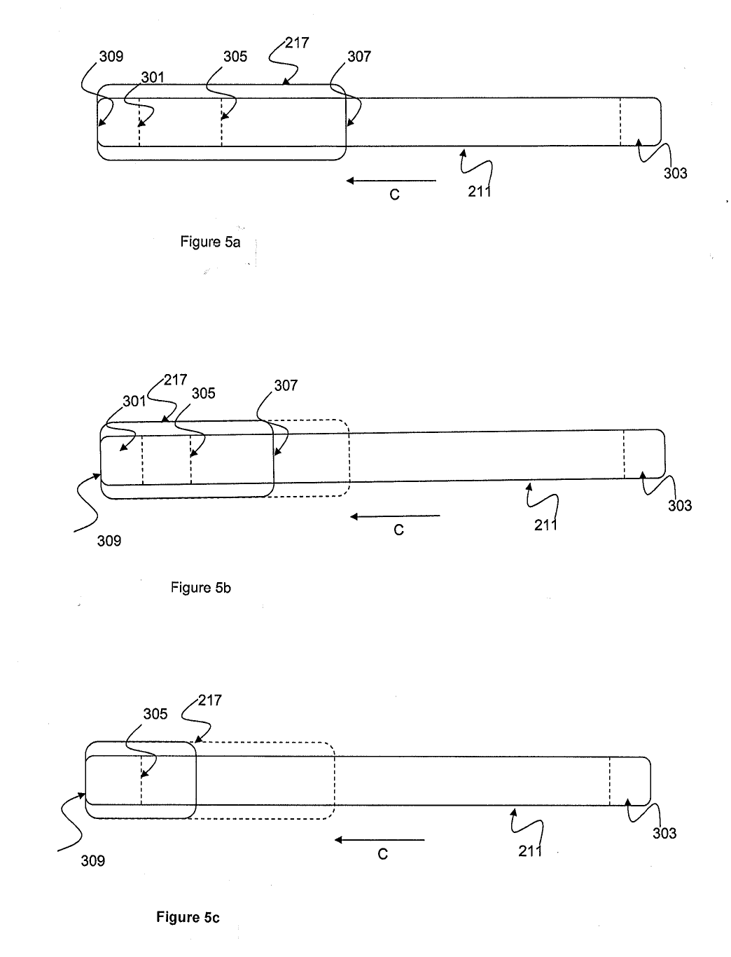

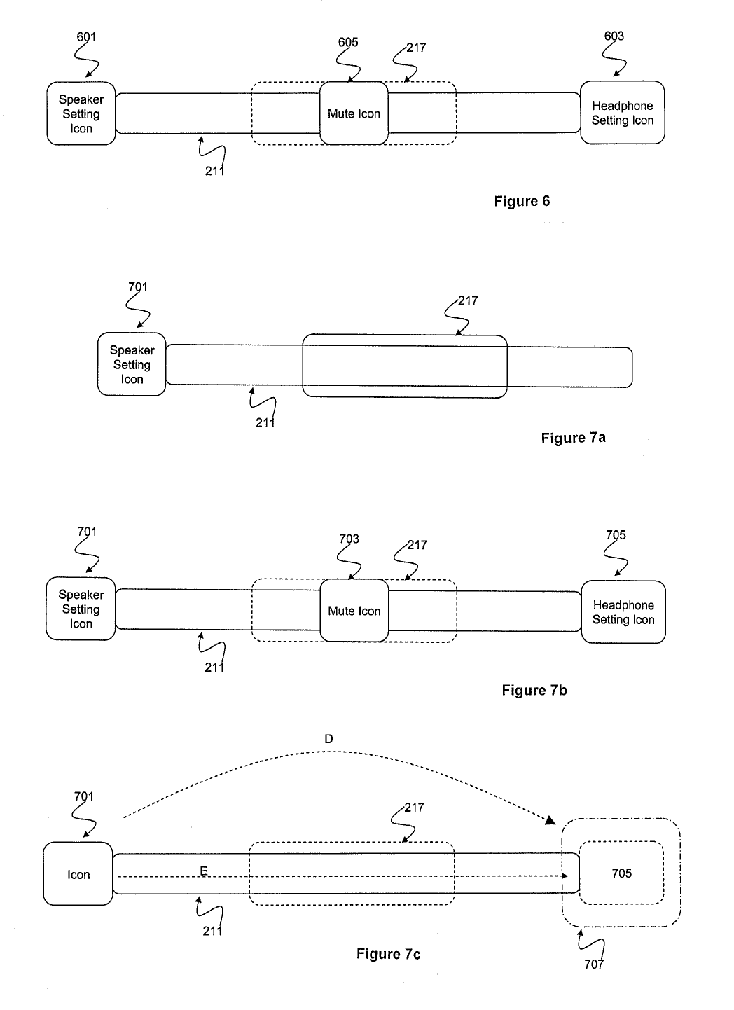

FIG. 6 is a schematic block diagram of a dynamic range control according to an example. A headphone setting icon 601 and a speaker setting icon 603 are provided at either end of the volume bar 211. In a speaker mode icon 603 is visible. In headphone mode, icon 601 is visible. Both have been shown in FIG. 6 for the sake of clarity. In an alternative example, both can be visible at the same time. In order to allow a user to determine which mode a device is operating in, an icon can be highlighted—it can be in a different colour to the other icon, or otherwise highlighted in some way which makes it obvious to the user which mode the device is operating in.

The icons 601, 603 can act as stops at either end of the volume bar 211 which prevent a user from trying to select a volume level which is higher or lower than permitted by the system in question. For example, in a speaker mode, icon 601 at the far quieter end of the control can act as a ‘stop’ to ensure that the level cannot go too low. In a headphone mode, icon 603 at the far loud end of the control can prevent a user from selecting a dangerous volume level, and can place the dB transition points from control 217 regions values which are more suitable for headphone use for example. In an example, icons 601, 603 are adjacent to either end of a volume bar 211 in order to provide a visual indication of their use as ‘stops’, as shown in FIG. 6. Other alternative positions are available.

According to an example, a trigger event which can be an event which is carried out on a mode icon or a mute button can cause the control window 217 to disappear and both mode icons to become visible. In the middle between the two mode icons a mute image icon 605 can appear. To un-mute, the user can chose between either speakers or headphones using the appropriate mode icon.

FIGS. 7a-c are schematic block diagrams of a dynamic range control according to an example. In FIG. 7a a device is operating in a specific mode, such as a mode in which output audio is processed to be suitable for speaker output. Accordingly, the speaker icon 701 is visible or otherwise highlighted in order to make it apparent that the device is operating in such a mode. In order to switch modes, as described above, a user has two options. In FIG. 7b, the output audio is muted as described above. Upon muting, several icons appear for a user. Icon 703 represents an indication for a user that the output audio is currently muted. Icon 705 is an alternative mode selection icon, such as a headphone mode icon for example. In order to switch modes to the alternative mode represented by the icon 705 the user can simply select, either by clicking or tapping for example, the icon 705. At this point, the audio is unmuted and the mode associated with icon 705 is selected. The change of mode will typically result in a change to the processing which is applied for an output audio signal.

In FIG. 7c, a mode change is effected in an alternative way to that of FIG. 7b. Whilst operating in a mode represented by icon 701, a user can switch modes by moving the icon 701 to a different position with respect to either the volume bar 211 or the control 217. In an example, a user can move the icon 701 to the other end of the bar 211 to invoke a change in the mode of operation. When within a predetermined vicinity at the end of the bar 211, the icon 701 can change into an icon 705 representing an alternative mode of operation. In this instance, a muting operation would not be required, and there would be no discernible gap in the output audio.

In an example, an icon can be shifted, and a mode therefore changed, only by moving an icon substantially through the control 217, as depicted generally by direction arrow E. Alternatively, any movement (which can be a movement outside of control 217 such as shown generally by arrow D) can be used.

For example, to switch from a speaker mode to a headphones mode, a user can move icon 701 to the other end of the bar 211, at which point it can change into the icon 705 indicating theta corresponding change in mode has occurred. The change of mode can occur at the point at which the icon 701 enters the aforementioned vicinity, depicted generally by the area 707, or can occur at the point at which the user ceases to move the icon and once it has been ‘captured’ in the area 707. In such an example, ceasing to move the icon 701 in the area 707 can cause it to ‘snap’ into a predetermined position, such as a position at the end of the bar 211 and change to an alternative icon such as 705 indicating the change of mode.

Moving an icon from one position to another can be effected using an input device such as a mouse or trackpad and by ‘grabbing’ the icon to be moved, and dragging it whilst selected. Alternatively, a touch gesture can be used in which a finger or other suitable implement is used to grab the icon to be moved and moving it across a touch sensitive display whilst it is still ‘grabbed’. Alternatively, a touch gesture can be provided in which a user ‘swipes’ an icon from one position into the general vicinity or direction of the icon 705 in order to effect the change. The icon may have to move a predetermined minimum amount in a predetermined direction before a change in mode is effected.

It will be appreciated that although reference has been made herein to single and double finger taps or device clicks or similar, or other gestures for a touch sensitive device which are designed to effect certain settings, modes and functions for a device, other interactions are possible. For example, a single or double tap or click can be replaced with any number of other suitable interactions which can be touch based gestures or input device based commands.

Furthermore, the placement and function of certain icons and modules has been described with reference to certain examples. However, it will be appreciated that the placement, design and function of icons, mode buttons and modules etc. can be varied according to the device in use, user preference, content provider preference and branding and various other factors. Accordingly, the above or that depicted in the figures is not intended to be limiting.

According to an example, there is provided an automatic dynamic range control method and system which provides a processed audio signal on the basis of a listener's DRT. Multiple layers of compression and dynamic range control operate to map an input signal to a desired DRT of a listener in a listening environment whilst performing a minimal amount of dynamic range compression. In an example, coefficients related to time scales over which compression can be varied are selected on the basis of psychoacoustic metrics. Accordingly, the scales are general to humans.

The DRT for a listener embodies a desired audio treatment in a listening environment, and is characterised by a dynamic range window giving a preferred average dynamic range region plus a dynamic range headroom region for an output audio signal. For a signal whose dynamic range is within the window characterising the DRT in the environment in which the signal is present, narrative and the main instruments in a piece of music for example can be easily heard and comprehended, and sudden disturbances in the form of loud effects, distortion and other such sounds do not affect the signal (inasmuch as the listener will typically not be inclined to desire a change in the level of volume of the signal as a result of the loud effects etc.). If, however, the level of the signal fluctuates outside of the DRT window, there can be a tendency for a listener to seek to adjust the volume of the signal to compensate. This is typically because sounds will either appear too soft or too loud for the user.

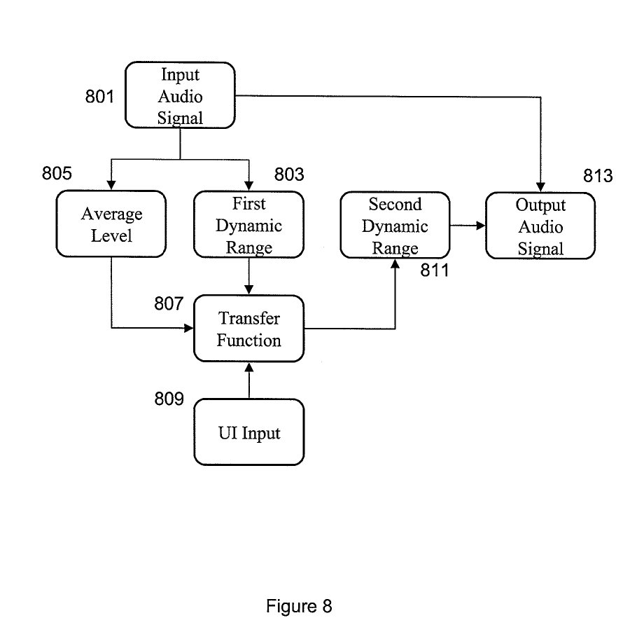

In an example, an input audio signal is processed in order to determine an average value for the volume level of the signal. The average value is constrained within a selected central region of a window control which is used to control the dynamic range of the output audio signal so that the DRT of the user in the environment in question is not exceeded (in either of the upper or lower bounds of the dynamic range in question). At a user device with a display, a volume control to control the volume level of the output audio signal of the device can be displayed for a user. In an example, the volume control includes a dynamic resizable window control to control dynamic range of the output audio signal according to a method as is described below with reference to FIGS. 8 to 15.

FIG. 8 is a schematic block diagram of a method according to an example. An input audio signal 801 can be any audio signal including a signal which is composed of music, spoken word/narrative, effects based audio or a combination of all three. For example, an input audio stream 801 can be a song, or a movie soundtrack. Input audio signal 801 has a first dynamic range 803 associated with it. The first dynamic range 803 represents the dynamic range of the input audio signal 801, and can be any dynamic range from zero. According to an example, an input dynamic range from an input audio signal 801 is not calculated. In block 105, the average level of the input audio signal 801 is determined. In an example, a running RMS of the signal 801 is computed using a selected averaging length.

In block 809, input is received representing a listening environment. The input can be received using a user interface (UI) which can provide multiple selectable options for a listening environment, at least. For example, an environment could be: cinema, home theatre, living room, kitchen, bedroom, portable music device, car, in-flight entertainment, each of which can have suitable selectable elements in the UI to enable a user to execute environmental dependent processing. In an example each of the environments has a different DRT associated with it which is related, amongst other things, to the noise floor of the environment in question. For example, the DRT for an in-flight entertainment environment will be smaller than that for a cinema environment due to differences in the noise floors associated with these environments as a result of ambient noise levels (the noise floor in an in-flight entertainment situation being relatively higher than that of the cinema environment for example).

In block 807 a transfer function is provided. The transfer function is determined using the input from block 809 representing the listening environment, and using the average level 805 of the input audio signal 801. In an example, the transfer function 807 is used to map the first dynamic range 803 to a second dynamic range 811. An output audio signal 813 with the second dynamic range 811 is generated from the input audio signal 801.

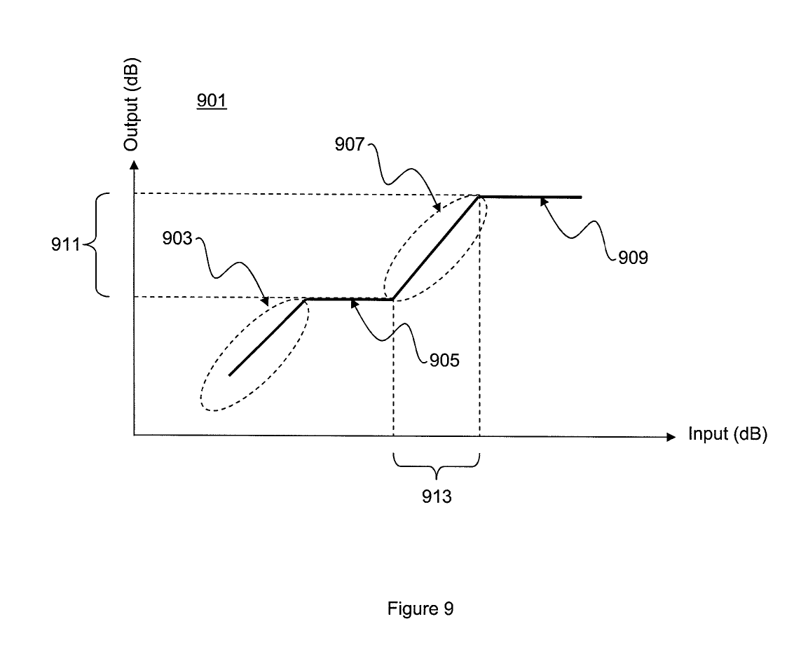

FIG. 9 is a schematic representation of a transfer curve according to an example. The transfer curve 901 has several portions depicted generally at 903, 905, 907 and 909, and is used to map a value for a dynamic range value of an input audio signal (Input (dB)) to a dynamic range value for an output audio signal (Output (dB)). Accordingly, transfer curve 901 is a graphical representation of a transfer function 107. The transfer function 107 therefore defines how different signal levels are scaled or mapped. In an example, in order to minimise perceivable processing artefacts in an audio signal, the transfer curve in the region of DRT for the listening environment in question is substantially linear that is, signals are scaled substantially in direct proportionality in region 907. The region 907 is therefore selected to coincide with a DRT window for an environment, such that an output signal has a dynamic range corresponding to the DRT of a listener in that environment.

Regions 905 and 909 correspond to regions of dynamic range control outside the DRT region 907. To confine signals to within the DRT region would require a limiter for an upper level control for region 909, and an aggressive expander for the lower level control for region 905. However, extreme transfer curves such as those of regions 905, 909 typically produce undesirable end results—that is, extreme upward expansion of a signal below the DRT region results in multiple zero-crossing distortions which occur when the transfer curve has a discontinuity at zero. Accordingly, the signal will have discontinuities every time it crosses zero as a result.

According to an example, in order to minimise the number of times that a signal is within the regions of dynamic range control (that is, when the signal is being modified in regions 905 and 909), the average level of the signal should lie within the DRT region 907 where the transfer curve is typically linear. To achieve this, a running RMS of an input audio signal is computed. According to an example, the RMS value is used to compute a gain value to shift the transfer function with respect to the input audio signal in order to align the linear portion to the average level of the input audio signal. Accordingly, the dynamic range of an output signal can be controlled so that the DRT of a user in a given listening environment is not exceeded (at either extreme) and the quality of the signal which is perceptible by the listener is not compromised. That is, by maintaining a level of dynamic range control in which signal changes are minimized as a result of an environment-dependent DRT shift, an output signal can be generated which improves a user experience within the sound environment in which they are listening.

In an example, the average level of the input audio signal is determined using an RMS measure of the input audio signal with an averaging length greater than a predetermined minimum value. For example, the averaging length can be a time period which is greater than the typical memory time of humans for a perceived sound level. When exposed to a sound with a consistent level, and given time, listeners typically lose sight of how loud or how quiet the sound is because there is no basis for reference. It is at the changes from one volume level to another where there is the strongest sense of the current loudness, but the overall level does little to affect the overall level of perceived loudness. Therefore, by setting an averaging time to be on the scale at which the brain tends to forget the volume level at the beginning of an interval, the effect of changes on the overall level of the signal will be slow enough for listeners not to perceive what is happening. For times shorter than this, the transfer curve ensures that the dynamic range of the signal is within tolerance. According to an example, an averaging time of the order of several seconds to several minutes or more can be used. Averaging time can vary depending on user input relating to a DRT. For example, a user input representing a larger DRT can have a slower rate of change. Expansion and limiting typically hides the rate of change for smaller selected DRT sizes, but it will also decrease how hard a limiting region is working, especially for small DRT ranges.

When the input audio has an RMS that lies within region 903, a very large gain would be produced, which tends to infinity as the signal RMS tends to zero. To ensure this does not happen and to ensure that quiet sections of the input audio are not processed to be higher in volume than the sections that should be high in volume, the averaging happens in two steps.

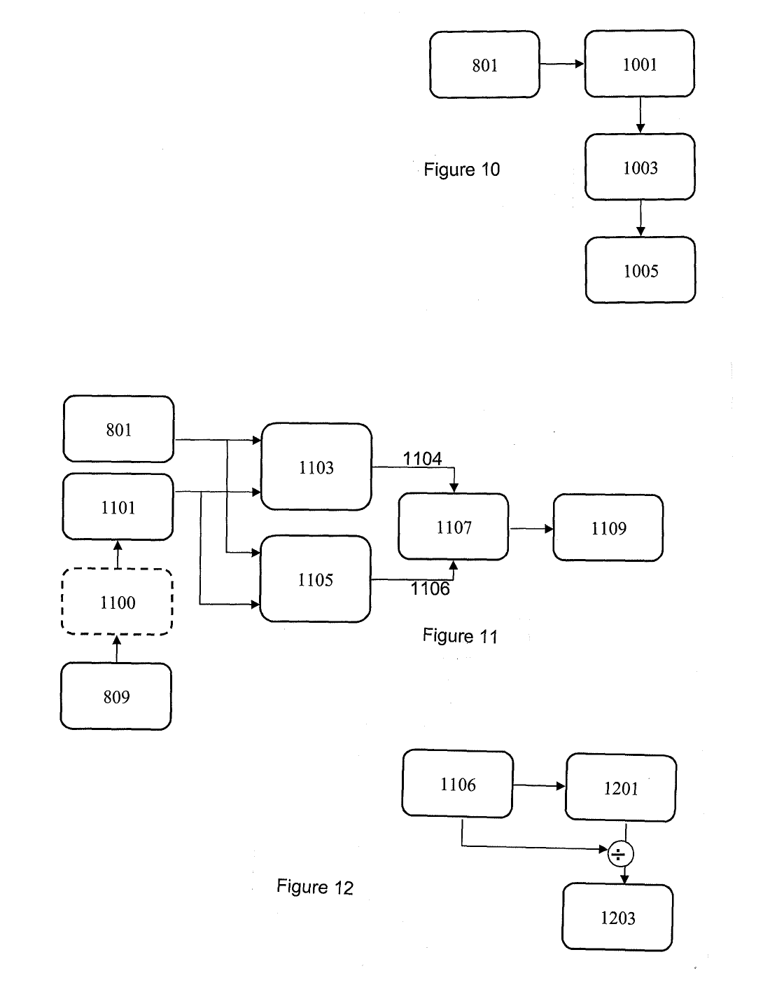

FIG. 10 is a schematic block diagram of an averaging method according to an example. Initially, an input audio signal 801 is averaged over a short timescale, such as of the order of a second. In block 1003, if the value computed for the short scale average implies that for that time the signal would be inaudible (even in an ideal listening environment) then it is deemed that these parts of the signal should not be expanded. A new function of time is therefore defined which takes a cut-off value such as 0.003 or takes the value of the average of the signal over the past second at time t otherwise if the average is above a minimum threshold for example. The cut-off can be a value which is an adaptive signal dependant value based upon the measured noise floor of the input audio for example. In block 1005, the new function is averaged over a predetermined psychoacoustic timescale and used to define a gain value 1007. Accordingly, the playback level will be low for fade-outs, no that the sound will emerge from inaudible, just as it does in a mastering house for example.

An 8 point cross-correlation approximation is calculated, but it is the maximum level from any one of the 8 feeds that is taken. A divide is not used to make a comparison with the input signal—a binary comparison is made where the direct and thus ‘perfect correlation’ result is multiplied by a threshold that is approximately 0.9. If any of the other 8 correlation measures exceed 0.9 of perfect, the input is considered signal. This binary feed is then filtered over a sensible length scale such as 6 ms. For tone this leads to the value 1 for almost all frequencies. The technique also returns 0 for white and pink noise and other similar noises. However the technique doesn't give a good result for environmental noise, or for input signals such as music.

For professional content, dither and electrical noise is more prominent than acoustic and environmental noise (mainly due to the prolific use of non-real-time noise reduction techniques). This means that triggering and creating a noise floor estimate driven by this technique combined with analysis of the amplitude leads to usable results. However for signals that have high acoustic noise such as many telephone calls the results are less good. The variance in the correlation of four of the correlation bands is then analysed. If this variation is significant, the input audio must have changed, ie. transitioned from low level noise to signal (or similar). This trigger can be used as a basic approximation to scene analysis. This trigger timing, compared with the change in the instantaneous level, enables the noise floor and signal level for noises that are on the whole deemed to the signal by the basic 8 band correlation measure to be gated more correctly. Acoustic noise also has the tendency to have higher levels of correlation variation than even music, thus rapid, repeated triggers suggest that the signal is acoustic noise. This can be used to make reduce the level of the noise further.

A large proportion of music and even speech has a high correlation when at constant tempo. A basic tempo meter can also be used as a measure of the presence of music to help with the setting of the noise floor and gate points.

Upward expansion (region 905 of FIG. 9) is difficult to achieve musically without significant look ahead (i.e. knowing what the signal will be in the future). Such extreme expansion can result in the signal overshooting the desired threshold for short periods of time unless rapid gain correction is used. However rapid gain changes create undesirable distortions. According to an example, extreme levels of upward expansion are achieved by separately processing the signal in two different ways that, when summed together give the required expansion. This signal is than limited (region 909 in FIG. 9) in a similar way to achieve sound within the DRT region 907.

In an example, upward expansion of an audio signal can be achieved by compressing the dynamic range to zero and setting the playback level to be at the lower threshold. Accordingly, for any input level, the signal will be at least at the lower threshold.

Another copy of the audio can then be added at the correct level so that the signal RMS rises above the lower threshold and towards the upper threshold. By applying a similar process in the expansion region (region 909), a signal within the DRT can be obtained. The extreme compression needed to create a zero dynamics version of an input signal is in general masked by the second signal added on top. In an example, the playback level of this zero dynamics signal is at the level of ambient noise. Thus, if distortion harmonics created by compression have an amplitude below the amplitude of the signal being compressed (which is at the noise floor level), the distortions will be masked by the listening environment and therefore be inaudible.

For stereo processing, two input channels (left and right) are turned into four input channels according to an example: left, right, mid (the sum of left and right), and side, (the difference between left and right). The four input channels (feeds) are processed independently of each other, except for the overall averages which define the overall driving gains for expansion and memory rate feeds. In an example, these are taken as the average of the left right mid and side level post filtering. Before limiting, the mid and side feeds are turned into left and right feeds and combined in equal measure with the processed left and right feeds. In an example, the left and right channel are then limited independently of each other.

FIG. 11 is a schematic block diagram of a method for processing a stereo signal according to an example. User input representative of a listening environment is provided via a UI in block 809. A DRT 1101 can be selected on the basis of the selected listening environment. Accordingly, multiple different DRT metrics can be provided which map to respective different listening environments. For example, where the selected listening environment is a cinema, the DRT metric can provide a preferred average dynamic range window from around −38 dB to 0 dB, and a dynamic range headroom (peak) from around 0 dB to +24 dB. An in-flight entertainment listening environment can provide a preferred average dynamic range window from around −6 dB to 0 dB, and a headroom from around 0 dB to +6 dB. Other alternatives are possible. DRT metrics can be stored in a database 1100. That is, a selected listening environment can map to a DRT metric from database 1100 which provides the DRT 1101.

In an example, input from a UI in block 809 can be in the form of input representing multiple sliding scale values which can be used to define a DRT metric. That is, a user can use a UI to select values for a preferred average dynamic range window and a dynamic range headroom. Such a selection can be executed by a user entering specific values using a sliding scale (or otherwise, such as raw numeric entry for example), or by using an interface which allows easy selection of values, such as a sliding scale which provides only a visual representation for a DRT metric. In the latter case, the actual values selected for a DRT metric may be unknown to a user, as they may simply use a UI element to provide a range within which they wish to constrain an audio signal for example.

An input audio signal 801 is provided, and both signal 801 and DRT 1101 are input to blocks 1103 and 1105. Block 1103 is a pre-processing filter which applies a gain value to each of the left, right, mid and side channels of the input signal 801. In an example, the pre-processing filter can be a k-filter which includes two stages of filtering—a first stage shelving filter, and a second stage high pass filter. In block 1105, zero dynamic range and playback level at lower threshold processing occurs on the left, right, mid and side channels of signal 801. In block 1107 the processed signals from blocks 1103 and 1105 can be combined and converted back to left and right channel signals only in block 1109.

According to an example, the signal feed used for expansion is averaged with a relatively short average (of the order of ˜2.4 seconds for instance) and is used to define a gain which, when applied to the original signal produces a signal that has a constant RMS of 1 for the same averaging time. This constant signal 1106 is the output for the first set of processing on the second signal stream from block 1105. Similarly, the memory rate signal from the first feed from block 1103 is referred to as 1104. According to an example, this signal still needs further compression, which is achieved as described below. The signal is finally scaled by a value which places it at the bottom of the DRT. This is done to maintain values near the number 1, which minimises discretisation error.

A digital hard clipper (whereby the signal is simply set to a certain threshold value when it goes beyond it) applies a gain reduction for the shortest amount of time, and uses the exact level of gain reduction required to ensure the signal never exceeds the limit. Accordingly, when the signal is within the limit, a clipper has no effect. However, due to rapid changes in the gain caused by a digital hard clipper, the level of distortion harmonics can be too strong and of an unpleasant unmusical character (unless an aggressive, painful, hard hitting sound is the desired goal). Smoothing the transfer curve provides smoother distortion harmonics even though a small amount of compression is applied when it does not need to be even when the signal is below the threshold. According to an example, a different method is used.

FIG. 12 is a schematic block diagram of a method according to an example. A clipped version 1201 of 1106 divided by 1106 is defined as a gain reduction envelope (GRE) 1203 according to an example. The GRE, if multiplied with the original signal gives the clipped signal. According to an example, the GRE can be smoothed in time by averaging it over a certain timescale. If the original signal is a continuous tone (i.e. sine wave with constant amplitude), then the smoothed GRE will be approximately a flat line provided the averaging is done over a sufficiently large timescale. Therefore multiplying 1106 with the smoothed GRE would simply have the effect of scaling it so that its peak is at the threshold. If the signal varies in time in such a way that compression is needed initially, but not later (a constantly decreasing in amplitude, transient signal), compression would fade away on the timescale of the averaging of the GRE. However, once the signal drops below the threshold, the smoothed GRE will take a moment to respond. This will mean that after a transient sound there will be a moment of lower amplitude, giving rise to an effect known as ‘pump’.

In order to minimise distortions, the GRE is smoothed with multiple single pole low pass filters. In an example, the GRE is smoothed at the aural reflex relaxation time of ˜0.63 Hz using four identical single pole low pass filters. The aural reflex relaxation time is the amount of time it typically takes for the muscles which contract when a loud sound is incident upon the ear to relax. This is a useful psychoacoustic timescale as the ear-brain system learns to correct sounds which are heard when the aural reflex occurs—thus, altering sound at this timescale tricks the brain into thinking its aural reflex has relaxed, which implies that the preceding sound was loud.

When driven with a steady state sine wave, the filtered GRE does not typically go to a small enough value to achieve limiting. According to an example, a level correction for steady state 1203 is therefore applied to the smoothed GRE so that it does so. This correction is derived from the average level of gain reduction relative to the required minimum level. This correction is pre-calculated and applied using a polynomial. Therefore, even after smoothing the GRE with a single pole filter, steady state sounds peaking over threshold reduce the gain by the amount to limit the signal without any clipping.

Put another way, the GRE created to limit steady state sounds does not typically provide sufficient gain reduction to cause limiting post filtering, unless the steady state sound is a digital square wave for example. Because of this the GRE is processed in an example. The processing alters the GRE for any driving signal to be similar to that created by a square wave of the same amplitude. To achieve this, the lowest value of the GRE is held until the input signal used to define the GRE goes through a zero crossing point (a sample at which the sign of the signal flips from positive to negative or negative to positive). At the zero crossing points, the hold of the minimum is reset to the current GRE value. The result is that the GRE is altered to be more comparable to that formed from a square wave (and is identical for the portion of the wavelet after the minimum in the GRE has occurred). The GRE may still provide insufficient gain reduction to cause limiting to all steady state sounds. In an example, a correction polynomial can therefore be applied to the altered GRE on that post filtering, sine tones are limited properly. This typically leaves triangle waves and most impulse trains mildly under compressed, with square waves mildly over compressed. However, the deviation in gain reduction is significantly less than if the polynomial required in this instance is applied without the ‘hold until zero crossing point’ alteration.

The points in time where the zero crossing points take place are affected by the presence of DC in the signal. Because of this frequencies below 14 Hz can be removed using a high pass filter before any processing is performed in an example.

Typically, there are sounds present in most signals which have volume envelopes that vary faster than 0.63 Hz. Accordingly, a new fundamental GRE of the signal is formed. According to an example, this GRE is smoothed with another four identical single pole low pass filters tuned to ˜2.3 Hz, which is a temporal masking rate, instead of ˜0.63 Hz. The pump effect mentioned previously occurs similarly with uncompressed sounds due to a psychoacoustic phenomenon known as temporal masking. Temporal masking is when a low amplitude sound is inaudible due to a preceding high amplitude sound. The lack of audibility is perceived as quiet, so giving a similar effect to pump. Thus, pump can trick the brain into thinking this current sound was preceded by a loud sound, making the previous sound appear louder than its amplitude alone would suggest. Smoothing the GRE on a timescale similar to that of temporal masking will therefore result in a signal which the brain perceives similarly to the uncompressed one, making the required levels of compression more acceptable.

The distortion harmonics produced with this limiter would be more audible than with the first slower limiter, but because the slower limiter has come first, the faster limiter will perform less compression than if it was used on its own. This rate of compression is still too slow to catch transients however. Therefore, a ‘fast’ limiter is applied to the signal resulting from the second layer of limiting. According to an example, low pass filters on this third limiters GRE are tuned to 14 Hz. The ‘roughness’ caused by the beating of two frequencies differing by 14 Hz or more begins to be perceived by humans until the difference in frequency is so great that it is perceived as two separate tones. Compressing at a rate faster than 14 Hz leads to an added roughness to the sound, whereas slower than or at this rate only changes the dynamic character rather than the tonal character. As a result, there are no audible distortions without comparison such as listening to the original sound and the distorted one side by side repeatedly. After this third ‘limiter’ the signal is very compressed.

Typically, most musical material is not highly transient in nature, and the dynamic range is typically much less than 6 dB. By setting the overall average of the signal to be at the threshold, the compression is therefore always taking place. The compression does not alter the tone however, and so the result is that the signal is typically less than 3 dB away from being at the noise floor of the listening environment at all times.

Although the RMS level of a signal is the largest factor in its perceived loudness, some frequencies are perceived louder than others due to a plethora of factors. A K-filter, as described above, has been shown to typically offer a more accurate map of the input signal to loudness, such that finding the average of a signal that varies in its frequency content post filtering and averaging leads to a number that varies more closely to how a constant frequency balanced sound (e.g. shaped noise) sounds louder or quieter when varied by the same number of dB's. The filtering before averaging gives a better guide to how the signal will be perceived in loudness.

In an example, the signal resulting from the 14 Hz limiter is at the volume level of the noise floor, and is added to the signal 1104. Because the processing on the two feeds of FIG. 11 has not altered phase, the feeds add constructively. Therefore, on summing the signal, the result will almost always be above the noise floor and thus is assumed to be always audible (even if only just). According to an example, this summed signal is now limited so that the high volume parts of the signal never exceed the dynamic range tolerance (or a DAC output level). The second feed (404) is of a higher average volume than the compressed (14 Hz limited) version and thus masks the distortions in it. The result is a rich full sound with improved depth, which is only normally present in the mastering studio.

According to an example, the same three layer limiting technique is used in the final output limiting stage. However, in order to capture the remaining peaks without buffering a short sequence of samples that are about to be played (“look-ahead”), a clipper can be used. As discussed before, simply clipping the signal adds unwanted distortions. Therefore, a compromise is made to keep the processing as close to real time as possible while producing an acceptable level of distortions.

When two signals are multiplied together in the linear time domain, the result is a signal which contains the sum and the difference of the two frequencies. Therefore, multiplication of a low frequency tone with a high frequency tone will produce two tones close to the original high frequency tone. Because the rate of gain changes a clipper makes are very rapid, the GRE of a clipper has a very wide frequency content and so a large number of distortion products are created across the entire frequency spectrum. Typically, the human ear hears best near 3 kHz. Typically, most of the energy in music resides in frequencies which are very small compared to 3 kHz, and so the resulting distortions are near 3 kHz, which is undesirable. Thus, if the frequency content of the GRE can be reduced in amplitude in the frequency range where the human ear hears best, the audibility of the distortions will be lower and thus the result will be more pleasant on the ear.

In an example, by filtering the GRE with a finite impulse response (FIR) filter rather than an infinite impulse response (IIR) filter the signal, after multiplication with the filtered GRE, will not go above unity. A FIR filter consists of a set of coefficients which multiply the past and present input samples. These are then summed to give the output. The number of past input samples used defines the tap count—a 16 tap filter, as used in an example, uses the past 15 samples and the current sample. Typically, limiting occurs, but the frequency content of the filtered GRE will mean that the distortions produced by the smoothed clipper will be in the frequency regions where the ear is insensitive—i.e. at frequencies which are significantly higher or lower than 3 kHz.

A FIR filter capable of attenuating 3 kHz requires enough delay (look-ahead) to do so. At a sampling rate of 44.1 kHz (which is used in CDs and most other consumer audio formats), a filter of length 16 samples leads to a resolution of 2.756 KHz. In an example, an elliptic filter is used as it has good distortion-reducing characteristics when the first notch is set to the lowest frequency which can be attenuated for this filter length—that is, typically 2.756 kHz. The filter also mildly attenuates the high frequencies in a 16 tap implementation. An average filter (has) lower computational load while being similar to an elliptic filter and can be used in CPU-critical implementations in an example.

To ensure that limiting still occurs, the GRE is ‘held’ at the lowest local value for 16 samples and then tails off as if the hold was not present (but including the delay). The filter is designed by taking the filter with the desired characteristics and then making the coefficients positive only by subtracting the smallest coefficient value. Applying the modified filter to the GRE will now only produce positive values. By adding the coefficients together and dividing each coefficient by this total, a filter is obtained where the sum of the coefficients is unity. Therefore, if the filter is applied to a flat line of the length of the filter (the held value), the value of the filter at the and of the flat line is that same value. Thus, the filter will ensure limiting.

The result is a psychoacoustic smooth look-ahead limiter which allows for levels of limiting of signals many dB higher than that bearable with generic hard clipping. When combined with the previous three layers of ‘limiting’, very high levels of total gain reduction are acceptable.

One should note that the GRE ‘hold’ process also smoothes the GRE and alters its frequency distribution similarly to a low pass filter. The frequency response is similar to a sinc function tuned to 2.75 kHz at the first notch. The result is that for frequencies above 3 kHz the limiting is very smooth sounding, meaning that, for example, hi-hats and the top frequencies of a snare crack are very pleasantly limited.

Another advantage of this FIR based approach with a filter that is as short as possible, is that limiting occurs for the shortest acceptable time, which leads to the highest possible overall RMS level. This is in fact higher than musically achievable with hard clipping as more gain reduction can be applied with the FIR smoothed approach before it becomes unacceptably unpleasant. This allows the entire dynamic range available within the DRT of the environment to be utilised to its fullest and allows audio equipment with limited peak output to achieve greater perceived loudness.

The memory rate average is used to apply the overall gain, which places the level of the sound in the middle of the overall range. This happens so slowly that the change is inaudible. However, for the expansion region, and when the averaging time is small (as it is for small ranges), the gain change is audible. (i.e. modulation artefacts can be heard/perceived, but not distinctly such as distortions heard from a guitar amplifier.) A method of changing the gain has been found that provides a significant reduction in the audibility of these modulations, allowing for constant listening for very extended periods without listener fatigue. The method is described below.

The technique uses the following principle. Short term expansion is used to achieve long term compression. Compression by its very nature works against the envelope of the sound and reduces its variation, whereas expansion works with the envelope of the sound—increasing the variation. Both, however, alter the signal's envelope from its original shape and thus are distortions. This technique of achieving compression via expansion improves the sound of both the overall gain change and the expansion region, because the sonic/perceptual side effects of each technique are balanced against each other while still achieving the desired amount of compression.

The technique is capable of such high modulation of the signal without the perceptible artefacts, that the 3 compressors on the expansion region are no longer needed. This saves significantly on CPU resources. The use of distinct mid, side, left and right peak compression and limiting can be used on the limiting region, but the use of this expansion to achieve compression technique to perform the gain modulation is consistent with the functionality of an average compressor rather than a peak compressor. Average compressors reduce stereo image modulation as identical gain is applied to both the left and right channel. Because of this, only two (left and right) compressors and limiters are needed, rather than four (left, right, middle, and side). This enables significant CPU resource savings.

A K-filtered average of the signal over a “long” timeframe such as 25 ms for the expansion and compression regions and the memory rate average for the overall gain region is used as the basis for the compression. The 25 ms modulation rate is the fastest possible rate wherein the modulation doesn't produce tone-like distortion artefacts, but it does lead to a highly unnatural sound. Modulating at, or close to this rate is desirable because it enable the sound to have a perceived constant level. Another average over 6 ms is taken and used for the trigger for when to apply short term expansion/long term compression. If the 25 ms average dictates that the gain should go up, the gain is only allowed to move up when the 6 ms average has jumped by more than 4 dB from what it was 6 ms ago. The gain is also allowed to increase when the 6 ms average has fallen by 12 dB (again from 6 ms ago). A drop of this magnitude means that temporal masking is taking place, and this masking means that gain changes cannot be heard (i.e. the gain increase at the gain increase rate is inaudible for that moment in time). The gain is allowed to fall only when the 6 ms average falls 1 dB or more, or when the 6 ms average jumps by 12 dB or more. The gain is altered like a tracking divide approximation. The gain change is performed by a single multiplier of the current gain, with a number greater than one leading to an increase, and a number less than one leading to a decrease. A different rate (coefficient) is used for each different type of change that has occurred according to the 6 ms average. The equivalent one-pole filter for these rates has a period of around 55 ms.

On the design outlined, four divides need to be calculated per sample and per channel (one for the limiters for both the left and right channels, and three for the compressors for the left, right, middle and side channels). An approach utilising feedback of the gain reduction envelopes of the compressors enables the limiter and the compressors to be combined together. As stated, using the expand-to-compress loudness method for the overall level and the gain stage of the expansion region removes the need for the middle and side channels. The resulting sound is effectively identical to that heard from the original design (and arguably better), but the CPU usage is reduced significantly since the number of divides in this design is much smaller.

To aid a description of how this optimisation works a recapitulation of the high CPU technique is outlined again.

The FGRE is found and smoothed with a slow set of one-pole filters. This is multiplied with the original signal, and the process is repeated a further two times with faster sets of one-pole filters. This leads to a highly compressed sound but where the transients are handled excellently by the following limiter stage—resulting in a highly compressed yet musical output signal.

To simplify discussion for how the optimisation is performed, consider an example with just two compressor stages. When the fundamental GRE for the second (final) stage is below unity, the input is above threshold. The GRE for the first stage (that is to be filtered) is the product of the fundamental GRE of the second stage multiplied with the filtered GRE of the first stage. When the fundamental GRE for the second (final) stage is unity, the input is below threshold. But how much below threshold is unknown, so the filtered version of the GRE for the stages above the current stage in the chain are used as a proxy for the result that would have been obtained if an FGRE was known for all the stages (as in the original unoptimised implementation). The GRE for the first stage (which needs to be filtered) needs to be calculated differently when the input is below threshold. The second stage's filtered GRE is fast compared with the stage before it (in this instance the first stage), but behaves smoothly and continuously. Consequently, the GRE of the first stage is the fundamental GRE of the second (final) stage (which is unity, and thus can be omitted), multiplied with the filtered GRE of the second stage. This leads to results that are near imperceptibly similar to the original design. The only deviation from the original is that the release rate is slightly slower than the attack rate, (not equal as in the original), and that there is a slight increase in chatter but this is mild due to the smoothing applied to the stages above it in the gain reduction chain. Many sound engineers find a shorter attack relative to release to sound better, but this is debatable. Finding the optimum filtering coefficients is now harder, as the amount of nonlinearity in the system has increased.

This combined compressor approach can be taken for all the stages and cascaded. When this is done, we call the compressor the ‘triple comp’. Unfortunately, the number of multiply operations needed to calculate the new GRE for the first stage increases with the total number of stages. However, the below or above threshold logic “switch” to determine which method for how to calculate the GRE (that is to be filtered) for each stage to be used, is the same for all of the stages, thus adding minimal additional CPU cost to the total design.

The particular processor architecture used to process Level in a given implementation, and especially its ability to calculate divides at an acceptable rate, determines the savings achieved by using this method. In general, when the number of compressors is much larger than 3, the CPU advantages are reduced.

For integer implementations, bit-shifting is either cheap or free in terms of the CPU resources used. Quantising the filter coefficients to be powers of two can therefore lead to a significant reduction in the complexity in calculating the one-pole filters used in the compressors. As the unoptimised compressor design uses four one-poles with the same coefficient, the use of different coefficients can be used to increase performance. Using a one-pole filter that is “too slow” followed by another that is “too fast”, (due to the power-of-two quantisation) can replace the four same-coefficient one-poles to within an acceptable sonic accuracy, and makes the CPU improvement worth it.

For the final compression stage a divide is still needed to calculate the FGRE. This divide can be removed if it is combined into the limiter, and if the limiter uses the following approximation.

In the limiter, a hold is applied to the FGRE which is then smoothed. If a feedback approach is used (similar to that used in the optimised compressors), the divide can be replaced with a tracking divide which has the potential to reduce the CPU load significantly (CPU architecture dependant).

The input signal peak level is held for 16 samples. This is achieved using a shift register where the max of all values in the register is the desired output. The register is shifted each sample. The max between this and the threshold is taken, like that of the standard FGRE calculation method. A tracking divide approximation is then used to calculate the GRE. The tracking divide must be tuned to guarantee an acceptable accuracy (the better the accuracy, the less headroom needs to be left to ensure there is no clipping). The tracker must also ensure that there is no undershoot within 16 samples, so that on the 16th sample the value of the GRE is the correct value.

The advantages of this approach are twofold—it removes the need for a divide, and the need for smoothing, as both are achieved in the same function. Feeding this into the optimised triple comp has removed the need for a divide in the entire Level implementation. As well as reducing CPU, an increase in the ease of porting the algorithm from platform to platform has been achieved because as not all processors provide good divide approximations. Note that on platforms with good divide approximations that this approach may actually use more CPU.

When the input signal is “abnormal”, as is often found with telephone calls, the fixed gain limit ensured by using the −50 dB minimum input before averaging is ineffective. A more advanced approach is needed, but one that must be able to revert to something close to the original method for professional content, as it does work surprisingly well.

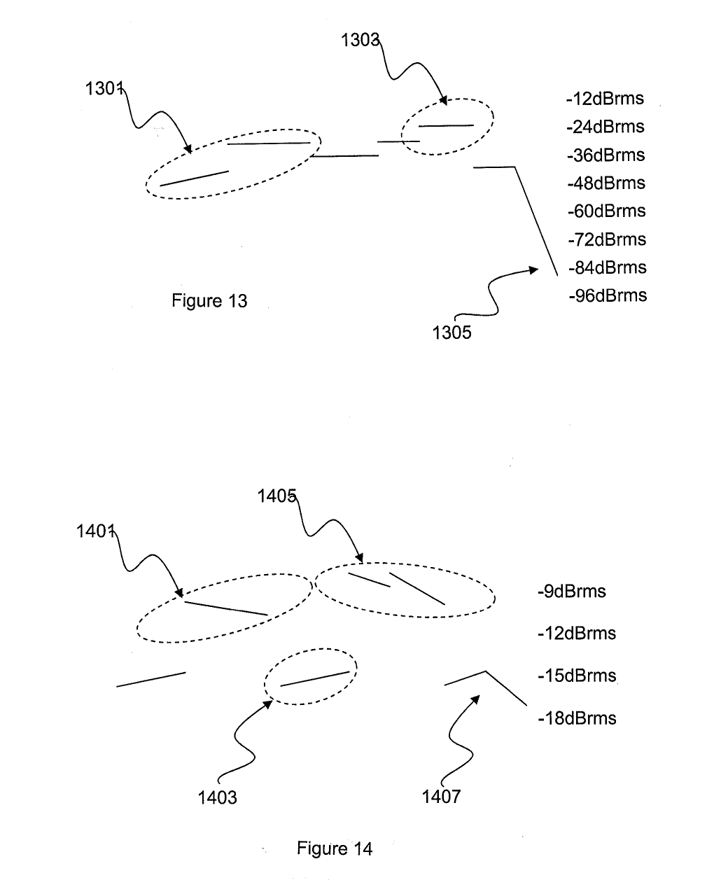

FIG. 13 is a schematic representation of the overall macro dynamics of a song. As generally depicted by 1301, the song starts quiet and crescendos, then jumps to a constant high level. It then jumps to a quieter section, and after this the music jumps to a high volume section which is roughly the same volume as that before, before jumping to a very high level denoted generally by 1303. After this ‘big finish’ the music jumps to a very quiet section before fading away to dither noise at 1305.

Consider that this song is being listened to in a car. The dynamic range tolerance thresholds are −7 dBFS rms for the upper limit, and with the lower threshold being −16 dBFS rms. The DRT is thus only 9 dB's which is significantly smaller than that of the input music, which is typically ˜24 dB's.

FIG. 14 is a schematic representation of the overall macro dynamics of the song of FIG. 13 following processing using a method according to an example. Assuming that no other tracks were playing before this song started, the very slow ‘memory rate’ average is zero at the start of the song. Once the track starts the RMS builds and the gain falls from zero to a more correct value no that by the time the song has reached half way through the first loud section of the song the level has effectively settled. The expansion feed has taken the input and squashed it to the lower threshold of the DRT. Once the loud section beings, the level of the input from the ‘memory rate’ gain movement is similar to that of the lower DRT threshold. The two levels add to give an overall level of −10 dB's which is just above the middle of the DRT range. Note though how the overall level has jumped up by ˜6 dBs at the start of this new section, a level of deviation not too dissimilar to that of the uncompressed version.

As the track continues through the first loud section, denoted generally by 1401, the RMS level grows and the output level of the second feed before the sum and limiter falls so that by the end of that section the level has fallen to the middle of the DRT to −11.5 dB's. Note that the rate that this has happened at is no slow that almost all listeners will not notice that the level was not constant. When the first quiet section, 1403, comes at the end of the first loud section 1401, the level will drop to the bottom of the DRT, but will still be audible at all times, by the end of the quiet section the level will have risen slightly towards the middle of the DRT.

At the jump to the second loud section, 1405, the level will jump to the top limit of the DRT and will be hitting the limiter at the end of the chain hard, the result will be a compressed sound but will be loud and with the minimal possible distortions. As the section continues, the RMS increases so the level is reduced. This means that when the very loud section hits there is still a level jump up back to maximum compression. Through this section the level falls back towards the middle of the DRT, and then jumps down to the bottom of the DRT as the ending quiet section, 1407, begins, the level rises and then falls with the fade getting closer and closer to the lower level of the DRT, but with details of the fade brought forward. Providing that the fade is slower than the ‘memory average’ level control, the fade will appear to keep happening even if only due to reduction in SNR and at a rate of 0.1 dB/s rather than 1 dB/s for example.

According to an example, the system and method described above has generally been described with reference to a single band, and using a fixed level as the ambient noise floor which is defined by user selection of the noise environment using a UI. In an example, a built in microphone of a portable player (or any other playback equipment) can be used to measure the noise floor of the environment continuously thereby allowing the DRT to dynamically adjust to that of the listening environment.

In an example, a multiband approach with noise floors of each band would allow music to be changed in tone so that different frequency regions of a signal are compressed by respective different amounts. Accordingly, the perceived tone in the listening environment would remain the same as that within a poor listening environment. A multiband approach could enhance the quality of music in environments with large amounts of low frequency rumble, such as in cars or planes for example.

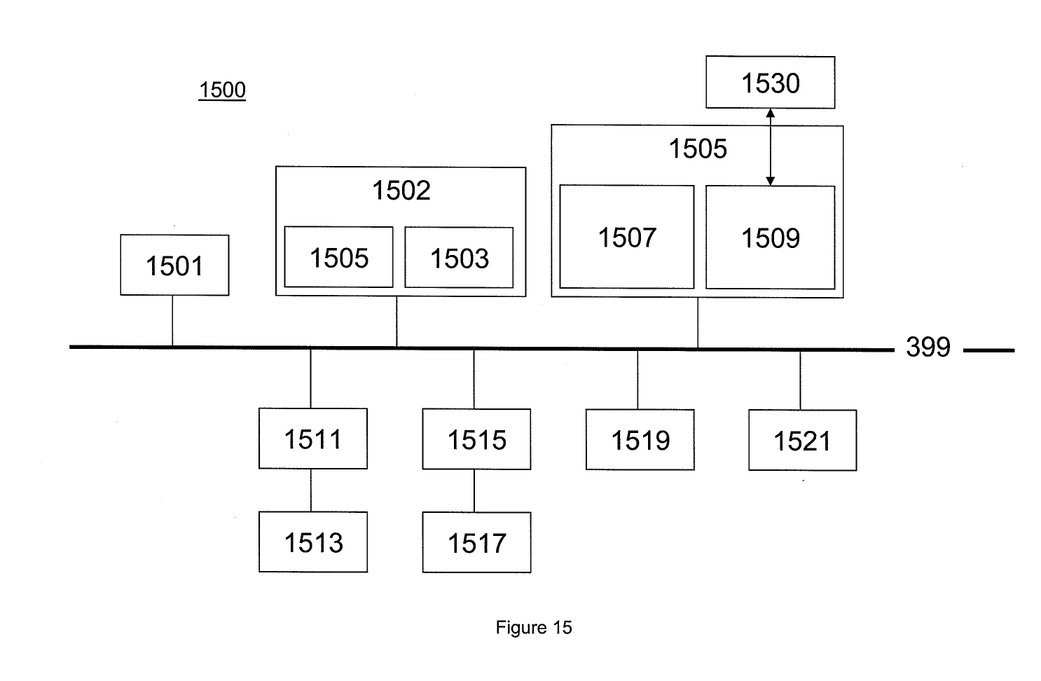

FIG. 15 is a schematic block diagram of a portion of an apparatus according to an example suitable for implementing any of the system or processes described above. Apparatus 1500 includes one or more processors, such as processor 1501, providing an execution platform for executing machine readable instructions such as software. Commands and data from the processor 1501 are communicated over a communication bus 399. The system 1500 also includes a main memory 1502, such as a Random Access Memory (RAM), where machine readable instructions may reside during runtime, and a secondary memory 1505. The secondary memory 1505 includes, for example, a hard disk drive 1507 and/or a removable storage drive 1530, representing a floppy diskette drive, a magnetic tape drive, a compact disk drive, etc., or a non-volatile memory where a copy of the machine readable instructions or software may be stored. The secondary memory 1505 may also include ROM (read only memory), EPROM (erasable, programmable ROM), EEPROM (electrically erasable, programmable ROM). In addition to software, data representing any one or more of an input audio signal, output audio signal, transfer function, average value for an audio signal and so on may be stored in the main memory 1502 and/or the secondary memory 1505. The removable storage drive 1530 reads from and/or writes to a removable storage unit 1509 in a well-known manner.

A user can interface with the system 1500 with one or more input devices 1511, such as a keyboard, a mouse, a stylus, and the like in order to provide user input data. The display adaptor 1515 interfaces with the communication bus 399 and the display 1517 and receives display data from the processor 1501 and converts the display data into display commands for the display 1517. A network interface 1519 is provided for communicating with other systems and devices via a network (not shown). The system can include a wireless interface 1521 for communicating with wireless devices in a wireless community.

It will be apparent to one of ordinary skill in the art that one or more of the components of the system 1500 may not be included and/or other components may be added as is known in the art. The system 1500 shown in FIG. 15 is provided as an example of a possible platform that may be used, and other types of platforms may be used as is known in the art. One or more of the steps described above may be implemented as instructions embedded on a computer readable medium and executed on the system 1500. The steps may be embodied by a computer program, which may exist in a variety of forms both active and inactive. For example, they may exist as software program(s) comprised of program instructions in source code, object code, executable code or other formats for performing some of the steps. Any of the above may be embodied on a computer readable medium, which include storage devices and signals, in compressed or uncompressed form. Examples of suitable computer readable storage devices include conventional computer system RAM (random access memory), ROM (read only memory), EPROM (erasable, programmable ROM), EEPROM (electrically erasable, programmable ROM), and magnetic or optical disks or tapes. Examples of computer readable signals, whether modulated using a carrier or not, are signals that a computer system hosting or running a computer program may be configured to access, including signals downloaded through the Internet or other networks. Concrete examples of the foregoing include distribution of the programs on a CD ROM or via Internet download. In a sense, the Internet itself, as an abstract entity, is a computer readable medium. The same is true of computer networks in general. It is therefore to be understood that those functions enumerated above may be performed by any electronic device capable of executing the above-described functions. According to an example, an input audio signal 1505 and an output audio signal 1505 can reside in memory 1502, either wholly or partially.

1. A method for adjusting dynamic range of an audio signal comprising:
providing an input audio signal with a first dynamic range;
mapping the first dynamic range to a second dynamic range using a transfer function selected on the basis of a listening environment defining a noise floor;
aligning a linear portion of the transfer function to an average level of the input audio signal; and
generating an output audio signal with the second dynamic range from the input audio signal.

2. A method as claimed in claim 1, wherein the listening environment determines a dynamic range tolerance and wherein aligning the linear portion includes constraining the average level of the input audio signal within the dynamic range tolerance for the listening environment.

3. A method as claimed in claim 1, wherein constraining the average level at the top of the dynamic range tolerance uses a switched coupled feedback path for the generation of the gain reduction envelope for multiple stages of compression.

4. A method as claimed in claim 1, wherein the average level of the input audio signal is determined using a one pole low pass filter in combination with an absolute sum and average of the input audio signal with an averaging length greater than a predetermined minimum value.

5. A method as claimed in claim 1, wherein aligning the linear portion to the average level includes using a gain value to shift the transfer function with respect to the input audio signal.

6. A method as claimed in claim 1, wherein the gain value shift of the transfer function is achieved by the use of short term expansion to achieve long term dynamic range compression or loudness normalization.

7. A method as claimed in claim 1, further comprising:
receiving user input representing a dynamic range window for substantially constraining the second dynamic range of the output audio signal.

8. A method as claimed in claim 5, wherein the transfer function is determined on the basis of the user input.

9. A method as claimed in claim 1, wherein the transfer function is dynamically adjusted in response to changes in a noise floor of the listening environment.

10. A method as claimed in claim 1, wherein a fade-in or fade-out portion of the input audio signal is maintained.

11. A method as claimed in claim 10, wherein maintaining a fade-in or fade-out includes preserving a noise floor of the input audio signal.

12. A method for adjusting the dynamic range of an output audio signal, comprising:
providing a dynamic range tolerance window to define a transfer function for a listening environment with a predetermined noise floor;
computing an average value for an input audio signal over a predetermined psychoacoustic timescale;
using the average to generate a gain value to shift the dynamic range tolerance window to align a linear portion of the transfer function with the average value; and
using the input audio signal to generate the output audio signal, the output audio signal having a dynamic range substantially confined within the dynamic range tolerance window.

13. A method as claimed in claim 12, wherein the average level of the input audio signal is determined using a one pole low pass filter in combination with an absolute sum and average of the input audio signal with an averaging length greater than a predetermined minimum value.

14. A method as claimed in claim 12, further comprising: receiving user input defining the dynamic range tolerance window.

15. A method as claimed in claim 12, wherein a fade-in or fade-out portion of the input audio signal is maintained.

16. A system for processing an audio signal, comprising:
a signal processor to:
receive data representing an input audio signal;
map the dynamic range of the input audio signal to an output dynamic range using a transfer function selected on the basis of a listening environment defining a noise floor and with a linear portion aligned to an average level of the input audio signal; and
generate an output audio signal with the output dynamic range, from the input audio signal.

17. A system as claimed in claim 16, wherein the average level of the input audio signal is determined using a one pole low pass filter in combination with an absolute sum and average of the input audio signal with an averaging length greater than a predetermined minimum value.

18. A system as claimed in claim 16, the signal processor further operable to align the linear portion to the average level using a gain value to shift the transfer function with respect to the input audio signal.

19. A system as claimed in claim 16, further comprising:
receiving user input representing a dynamic range window for substantially constraining the dynamic range of the output audio signal.

20. A system as claimed in claim 16, wherein the transfer function is determined on the basis of user input.

21. A system as claimed in claim 20, the signal processor to adjust the transfer function in response to changes in a noise floor of the listening environment.

22. A system as claimed in claim 16, the signal processor to maintain a fade-in or fade-out portion of the input audio signal.

23. A computer program embedded on a non-transitory tangible computer readable storage medium, the computer program including machine readable instructions that, when executed by a processor, implement a method for adjusting dynamic range of an audio signal comprising:
receiving data representing a user selection for a dynamic range tolerance to define a transfer function for a listening environment with a predetermined noise floor;
determining a transfer function based on the dynamic range tolerance; and
processing an input audio signal to generate an output audio signal using the transfer function by maintaining an average level of the input audio signal within a range defined by the user selection.

24. A computer-implemented method, comprising:
at a device with a display: displaying a relative loudness level control to control the volume level of an output audio signal of the device, the relative loudness level control including a dynamic resizable window control to control dynamic range of the output audio signal; and
processing an input audio signal to constrain an average value of the relative loudness level for that signal within a selected central region of the window control to control the dynamic range of the output audio signal.

25. A computer-implemented method as claimed in claim 24, wherein upper and lower bounds of the control represent upper and lower bounds for the dynamic range of the output audio signal.

26. A computer-implemented method as claimed in claim 24, wherein the device is touch screen display device, the method further comprising:
detecting a translation gesture for the window control by one or more fingers on or near the touch screen display; and
in response to detecting the translation gesture, adjusting the position of the window control to modify the relative loudness level of the output audio signal.

27. A computer-implemented method as claimed in claim 24, further comprising:
detecting a resizing gesture for the window control by one or more fingers on or near the touch screen display; and
in response to detecting the resizing gesture, adjusting the size of the window control to modify the dynamic range of the output audio signal.

28. A computer-implemented method as claimed in claim 27, wherein a resizing gesture includes at least one finger tap on or near the touch screen display in the vicinity of the control window.

29. A computer-implemented method as claimed in claim 27, wherein a resizing gesture includes a pinch or anti-pinch gesture using at least two fingers.

30. A computer-implemented method as claimed in claim 29, wherein the resizing gesture cyclically resizes the window control between multiple discrete sizes.

31. A computer-implemented method as claimed in claim 24, further comprising:
detecting a translation gesture for the window control by an input device; and
in response to detecting the translation gesture, adjusting the position of the window control to modify the relative loudness level of the output audio signal.

32. A computer-implemented method as claimed in claim 24, further comprising:
detecting a resizing gesture for the window control by an input device; and
in response to detecting the resizing gesture, adjusting the size of the window control to modify the dynamic range of the output audio signal.

33. A computer-implemented method as claimed in claim 32, wherein a resizing gesture includes executing a control button operation in the vicinity of the control window.

34. A computer-implemented method as claimed in claim 24, further including using a mode selection control, selecting a mode of operation for the dynamic resizable window control representing one of multiple modes with respective different ranges for the dynamic range of the output audio signal.

35. A computer-implemented method as claimed in claim 24, wherein an average relative loudness level over a predetermined period of time is substantially aligned with the centre of the dynamic resizable window control.

36. A computer-implemented method as claimed in claim 24, wherein the window control is moveable within a predetermined relative loudness range, the method further comprising shrinking the range of the dynamic resizable window control in response to the window control impinging on a portion of the predetermined relative loudness range at either extreme of said range to provide a reduced window control.

37. A computer-implemented method as claimed in claim 36, wherein the dynamic resizable window control is shrunk to a predetermined minimum.

38. A computer-implemented method as claimed in claim 37, further including providing a relative loudness level for the output audio signal in response to user input to shift the reduced window control past the portion at an extreme of the predetermined relative loudness range.

39. A computer-implemented method as claimed in claim 34, further including providing a mute control accessible via the mode selection control to mute the output audio signal.

40. A graphical user interface on a device with a display, comprising:
a relative loudness level control portion to display a relative loudness level for an output audio signal and to provide a range within which the relative loudness level can be adjusted; and
a dynamic range control portion including an adjustable window element aligned with the relative loudness level control portion to define a dynamic range for the output audio signal.

41. A graphical user interface as claimed in claim 40, wherein the size of the window element defines the dynamic range of the output audio signal.

42. A graphical user interface as claimed in claim 40, wherein a size of the window element can be cyclically adjusted between multiple discrete sizes.

43. A graphical user interface as claimed in claim 42, wherein adjusting a size of the window element is effected using any one or more of: one or more finger taps on a touch screen display for the device; user input from an input device for the device; and a resizing gesture on a touch display for the device.

44. A graphical user interface as claimed in claim 43, wherein the resizing gesture is a pinch or anti-pinch using two or more fingers.

45. A graphical user interface as claimed in claim 40, further including a mode selection.

46. A graphical user interface as claimed in claim 40, further including mute and reset selection controls.

47. A device, comprising:
a display;
one or more processors;
memory; and
one or more programs stored in the memory and including instructions which are configured to be executed by the one or more processors to:
display a relative loudness level control module to control a relative loudness level and a dynamic range for an output audio signal output from the device;
control the size and position of a dynamic range control window in response to user input; and
control a dynamic range of the output audio signal on the basis of the size and position of the dynamic range control window by constraining an average value of the relative loudness level for an input audio signal within a selected central region of the control window.

48. A device as claimed in claim 47, wherein the one or more processors are further operable to execute instructions to:
receive first user input data representing a position for the dynamic range control window; and
receive second user input data representing a size for the dynamic range control window.

49. A device as claimed in claim 48, wherein the second user input data is generated in response to one or more of: a tap, pinch or anti-pinch gesture on the display.

50.-54. (canceled)
